(19) United States
(12) Patent Application Publication
(10) Pub. No.: US 2026/0090166 A1
(43) Pub. Date: Mar. 26, 2026

(54) Display Device

(71) Applicant: LG Display Co., Ltd., Seoul (KR)

(72) Inventors: Yeonjun Oh, Incheon (KR); SungJoon Min, Goyang-si (KR); Dojoong Kim, Seoul (KR); JunHyuk Song, Seoul (KR); Taehyun Kim, Uijeongbu-si (KR)

(21) Appl. No.: 19/280,972

(22) Filed: Jul. 25, 2025

(30) Foreign Application Priority Data
Sep. 25, 2024 (KR) 10-2024-0130010

(51) Int. Cl. H10H 29/39

(52) U.S. Cl. CPC H10H 29/39

(57) ABSTRACT

A display device includes a stretchable lower substrate which is divided into an active and non-active areas, pixels in the active area and on the lower substrate, connection lines on the lower substrate and connected to each of the pixels, a stretchable upper substrate, and a pad pattern in the non-active area between the lower substrate and the upper substrate. The pad pattern may include a first lower pad plate pattern on which an input pad is disposed, a second lower pad plate pattern on which a chip pad connected to the input pad through a pad connection line and a driving chip connected to the chip pad are disposed, a lower pad line pattern which connects the first and second lower pad plate patterns, and an upper pad plate pattern which is disposed on the first and second lower pad plate patterns and the lower pad line pattern.

### CROSS-REFERENCE TO RELATED APPLICATION

This application claims the priority of Republic of Korea Patent Application No. 10-2024-0130010 filed on Sep. 25, 2024, which is hereby incorporated by reference in its entirety.

### BACKGROUND

### Field

The present disclosure relates to a display device, and more particularly to a stretchable display device which can be stretched.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Recently, a display device which is manufactured by forming a display unit and a wiring line on a flexible substrate such as plastic which is a flexible material so as to be stretchable in a specific direction and changed in various forms is getting attention as a next generation display device.

### SUMMARY

An object to be achieved by the present disclosure is to provide a display device which is stretchable in a pad area in which a driving chip and a plurality of pads are disposed.

Objects of the present disclosure are not limited to the above-mentioned objects, and other objects, which are not mentioned above, can be clearly understood by those skilled in the art from the following descriptions.

In order to achieve the above-described object, according to an embodiment of the present disclosure, a display device may include a lower substrate which is divided into an active area and a non-active area and is stretchable, a plurality of pixels which is disposed in the active area and on the lower substrate, a plurality of connection lines which is disposed on the lower substrate and is connected to each of the plurality of pixels, an upper substrate which is opposite to the lower substrate and is stretchable, and a pad pattern which is disposed in the non-active area between the lower substrate and the upper substrate. The pad pattern may include a first lower pad plate pattern on which an input pad is disposed, a second lower pad plate pattern on which a chip pad connected to the input pad through a pad connection line and a driving chip connected to the chip pad are disposed, a lower pad line pattern which connects the first lower pad plate pattern and the second lower pad plate pattern, and an upper pad plate pattern which is disposed on the first lower pad plate pattern, the second lower pad plate pattern, and the lower pad line pattern.

In order to achieve the above-described object, according to an embodiment of the present disclosure, a display device may include a lower substrate which is divided into an active area and a non-active area and is stretchable, a plurality of pixels which is disposed in the active area and on the lower substrate, a plurality of connection lines which is disposed on the lower substrate and is connected to each of the plurality of pixels, an upper substrate which is opposite to the lower substrate and is stretchable, a pad pattern which is disposed in the non-active area between the lower substrate and the upper substrate, and a driving chip disposed on the pad pattern. The pad pattern may include a plastic material.

Other detailed matters of the exemplary embodiments are included in the detailed description and the drawings.

According to the exemplary embodiments of the present disclosure, in a display device, a driving chip and a plurality of pads connected thereto may be disposed in a stretchable pad area.

Accordingly, according to the exemplary embodiments of the present disclosure, the display device may be stretchable even in a pad area in which a driving chip and a plurality of pads connected thereto are disposed.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view illustrating a display device according to exemplary embodiments of the present disclosure;

FIGS. 2 and 3 are enlarged plan views illustrating an example of a part A of FIG. 1 according to exemplary embodiments of the present disclosure;

FIG. 4 is a cross-sectional view illustrating an example taken along the line IV-IV′ of FIGS. 2 and 3 according to exemplary embodiments of the present disclosure;

FIGS. 5 and 6 are enlarged plan views illustrating an example of a part B of FIG. 1 according to exemplary embodiments of the present disclosure;

FIG. 7 is a cross-sectional view illustrating an example taken along the line V-V′ of FIGS. 5 and 6 according to exemplary embodiments of the present disclosure;

FIGS. 8A to 8I are process charts illustrating a manufacturing method of a display device according to exemplary embodiments of the present disclosure;

FIG. 9 is a cross-sectional view illustrating another example taken along the line V-V′ of FIGS. 5 and 6 according to exemplary embodiments of the present disclosure; and

FIGS. 10 and 11 are enlarged plan views illustrating another example of a part B of FIG. 1 according to exemplary embodiments of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately”or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

Advantages and characteristics of the present disclosure and a method of achieving the advantages and characteristics will be clear by referring to exemplary embodiments described below in detail together with the accompanying drawings. However, the present disclosure is not limited to the exemplary embodiment disclosed herein but will be implemented in various forms. The exemplary embodiments are provided by way of example only so that a person of ordinary skill in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When described as ‘coupled’ or ‘connected’, it may include being ‘coupled’ or ‘connected’ through one or more other components located between the two components, unless ‘immediately’ or ‘directly’ is used.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various exemplary embodiments of the present disclosure can be partially or entirely bonded to or combined with each other and can be interlocked and operated in technically various ways, and the exemplary embodiments can be carried out independently of or in association with each other.

Hereinafter, various exemplary embodiments of the present disclosure will be described in detail with reference to accompanying drawings.

A display device according to exemplary embodiments of the present disclosure is a display device which is capable of displaying images even in a bent or extended state and may also be referred to as a stretchable display device, a flexible display device and an extendable display device. As compared with the general display devices of the related art, the display device may have not only a high flexibility, but also stretchability. Therefore, the user may bend or extend a display device and a shape of a display device may be freely changed in accordance with manipulation of a user. For example, when the user pulls the display device by holding ends of the display device, the display device may be extended to the pulling direction of the user. Alternatively, when the user disposes the display device on an outer surface which is not flat, the display device may be disposed to be bent in accordance with the shape of the outer surface of the wall. Further, when a force applied by the user is removed, the display device may return to its original shape.

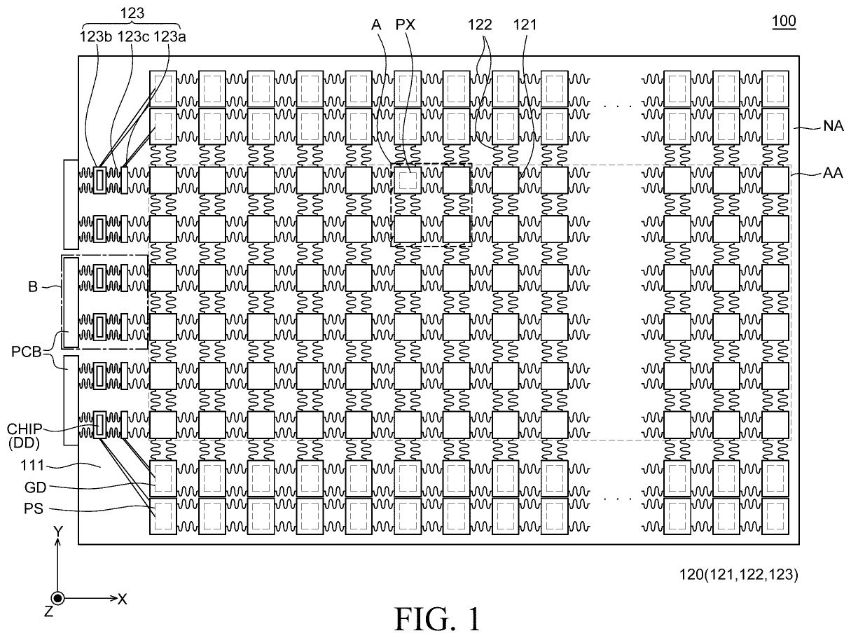

FIG. 1 is a plan view illustrating a display device according to exemplary embodiments of the present disclosure.

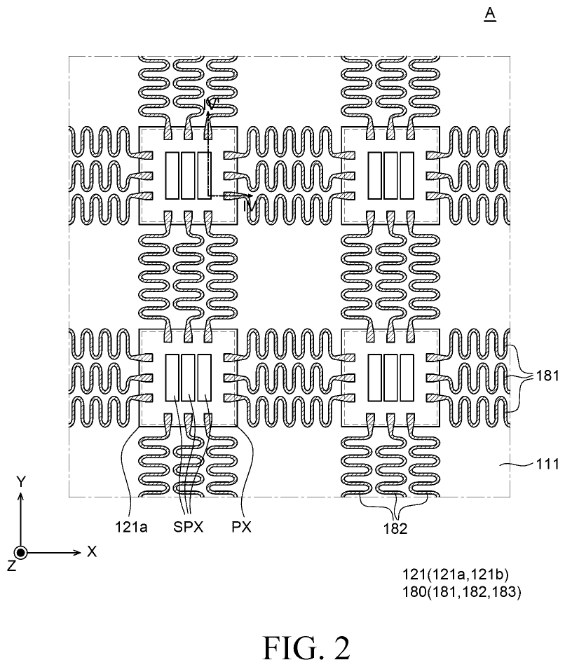

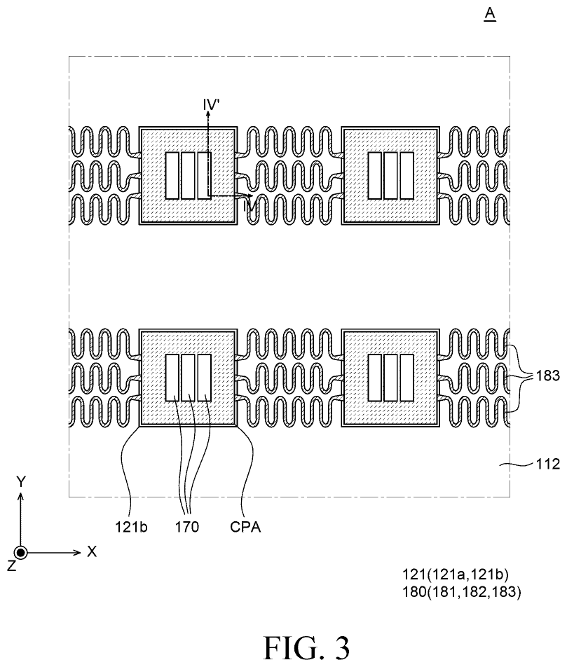

FIGS. 2 and 3 are enlarged plan views illustrating an example of a part A of FIG. 1 according to exemplary embodiments of the present disclosure.

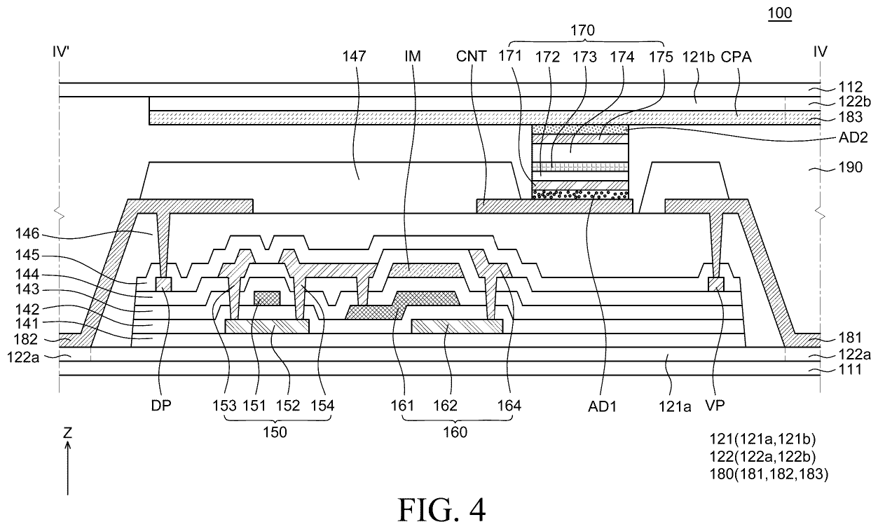

FIG. 4 is a cross-sectional view illustrating an example taken along the line IV-IV′ of FIGS. 2 and 3 according to exemplary embodiments of the present disclosure.

In the meantime, in FIG. 2, among components of the display device 100 according to exemplary embodiments, a lower substrate 111 and components disposed on the lower substrate 111 for the part A of FIG. 1 are illustrated. In FIG. 3, among components of the display device 100 according to exemplary embodiments, an upper substrate 112 and components disposed on the upper substrate 112 for the part A of FIG. 1 are illustrated.

Referring to FIG. 1, a display device 100 according to exemplary embodiments of the present disclosure may include a lower substrate 111, a pattern layer 120, a plurality of pixels PX, a gate driver GD, a data driver DD, and a power supply PS. In the exemplary embodiment, further referring to FIG. 4, the display device 100 may further include a filling layer 190 and an upper substrate 112.

The lower substrate 111 may support various components of the display device 100 and the upper substrate 112 may cover various components of the display device 100.

In one exemplary embodiment, the lower substrate 111 and the upper substrate 112 which are flexible substrates may include an insulating material which is bendable or extendable.

A modulus of elasticity of each of the lower substrate 111 and the upper substrate 112 may be several MPa to several hundreds of MPa. According to the exemplary embodiment, a ductile breaking rate of each of the lower substrate 111 and the upper substrate 112 may be 100% or higher. Here, the ductile breaking rate refers to a stretching rate at a timing when an object to be stretched is broken or cracked.

The lower substrate 111 may include an active area AA in which images are displayed and a non-active area NA excluding the active area AA. For example, in the active area AA, a plurality of pixels PX each including a display element and a circuit element may be disposed and in the non-active area NA, a gate driver GD and a power supply PS for driving the plurality of pixels PX disposed in the active area AA may be disposed.

The pattern layer 120 may be disposed on the lower substrate 111. To be more specific, further referring to FIG. 4, the pattern layer 120 may include lower pattern layers 121a and 122a and upper pattern layers 121b and 122b. The lower pattern layers 121a and 122a may be pattern layers which are disposed on the lower substrate 111 to be in contact with the lower substrate 111 and the upper pattern layers 121b and 122b may be pattern layers which are disposed on the upper substrate 112 to be in contact with the upper substrate 112.

Further, referring to FIG. 4, the pattern layer 120 may include a plurality of plate patterns 121 (including 121a and 121b) which is disposed as island shapes which are spaced apart from each other and a plurality of line patterns 122 (including 122a and 122b) which connects the plurality of plate patterns 121a and 121b.

To be more specific, referring to FIGS. 1 and 2 together, the lower pattern layers 121a and 122a may include a plurality of lower plate patterns 121a which are disposed as island shapes which are spaced apart from each other and a plurality of lower line patterns 122a which connect the plurality of lower plate patterns 121a, on the lower substrate 111. Each of the plurality of lower plate patterns 121a and the plurality of lower line patterns 122a may be disposed in the active area AA and the non-active area NA and on the lower substrate 111. Further, referring to FIGS. 1 and 3 together, the upper pattern layers 121b and 122b may include a plurality of upper plate patterns 121b which are disposed as island shapes which are spaced apart from each other and a plurality of upper line patterns 122b which connects the plurality of upper plate patterns 121b, on the upper substrate 112. Each of the plurality of upper plate patterns 121b and the plurality of upper line patterns 122b may be disposed in the active area AA and the non-active area NA and on the upper substrate 112.

In one exemplary embodiment, each of the plurality of lower plate patterns 121a disposed on the lower substrate 111 may be disposed so as to overlap each of the plurality of upper plate patterns 121b disposed on the upper substrate 112.

Referring to FIGS. 1, 2, and 4, on the plurality of lower plate patterns 121a, the plurality of pixels PX may be formed and on the plurality of lower plate patterns 121a, the gate driver GD and the power supply PS may be formed.

Further, in FIGS. 1 to 3, it is illustrated that each of the plurality of lower plate patterns 121a and the plurality of upper plate patterns 121b has a quadrangular shape, but is not limited thereto.

In one exemplary embodiment, each of the plurality of lower line patterns 122a and the plurality of upper line patterns 122b may have a wavy shape (for example, a sine wave shape), but is not limited thereto. Each of the plurality of lower line patterns 122a and the plurality of upper line patterns 122b may extend in a zigzag shape or have various shapes such as a plurality of rhombic substrates which is connected at their vertices to be extended.

In one exemplary embodiment, the pattern layer 120 further includes a plurality of pad patterns 123. A driving chip CHIP which is disposed between the lower substrate 111 and the upper substrate 112 and a plurality of pads connected thereto may be disposed on the plurality of pad patterns 123. The plurality of pad patterns 123 may include at least one of polyimide, polyacrylate, and polyacetate.

Referring to FIG. 1, the plurality of pad patterns 123 may be disposed in the non-active area NA between the lower substrate 111 and the upper substrate 112. For example, the driving chip CHIP disposed on the pad pattern 123 may be disposed in the non-active area NA between the active area AA and the printed circuit board PCB, for example, in the pad area so as to be connected to the printed circuit board PCB and the plurality of pixels PX, the gate driver GD, and the power supply PS disposed on the plurality of lower plate patterns 121a through the plurality of pads.

To be more specific, each of the plurality of pad patterns 123 may include a plurality of lower pad plate patterns 123a and 123b disposed as island shapes which are spaced apart from each other and the plurality of lower pad line patterns 123c which connects the plurality of lower pad plate patterns 123a and 123b. For example, the plurality of lower pad plate patterns 123a and 123b and the plurality of lower pad line patterns 123c are disposed on the lower substrate 111 to be in contact with the lower substrate 111. Each of the plurality of lower pad plate patterns 123a and 123b and the plurality of lower pad line patterns 123c may be disposed in the non-active area NA, for example, in the non-active area NA between the active area AA and the printed circuit board PCB.

The plurality of lower pad plate patterns 123a and 123b may include a first lower pad plate pattern 123a and a second lower pad plate pattern 123b which are disposed to be spaced apart from each other along the first direction X. The first lower pad plate pattern 123a may be disposed to be adjacent to the active area AA and the second lower pad plate pattern 123b may be disposed to be adjacent to the printed circuit board PCB. Further, the driving chip CHIP and the plurality of pads connected thereto may be disposed on the plurality of lower pad plate patterns 123a and 123b.

Further, as illustrated in FIG. 1, each of the first and second lower pad plate patterns 123a and 123b may have a rectangular shape having one pair of short sides extending along the first direction X and one pair of long sides extending along the second direction Y, but this is just illustrative. Therefore, the exemplary embodiment of the present disclosure is not limited thereto.

According to the exemplary embodiment, referring to FIG. 1, each of the plurality of lower pad line patterns 123c may have a wavy shape (for example, a sine wave shape), but is not limited thereto. Each of the plurality of lower pad line patterns 123c may extend in a zigzag shape or have various shapes such as a plurality of rhombic substrates which is connected at their vertices to be extended.

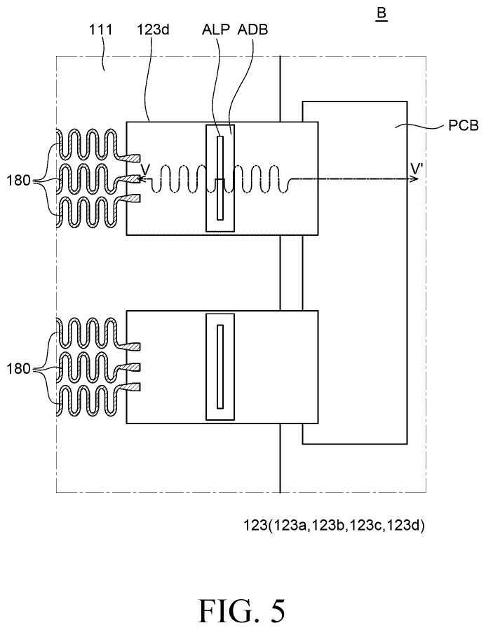

Even though it is not illustrated in FIG. 1, each of the plurality of pad patterns 123 may further include a plurality of upper pad plate patterns (for example, a plurality of upper pad plate patterns 123d of FIG. 5) disposed above the plurality of lower pad plate patterns 123a and 123b and the plurality of lower pad line patterns 123c. For example, the plurality of upper pad plate patterns are disposed on the upper substrate 112 to be in contact with the upper substrate 112. The upper pad plate pattern is a pattern which is disposed on the lower pad plate patterns 123a and 123b and the lower pad line pattern 123c to cover the driving chip CHIP and the plurality of pads disposed on the lower pad plate patterns 123a and 123b and may be disposed to overlap the lower pad plate patterns 123a and 123b and the lower pad line pattern 123c. The upper pad plate pattern will be described in more detail with reference to FIGS. 5 to 7.

In one exemplary embodiment, the plurality of lower plate patterns 121a, the plurality of upper plate patterns 121b, the plurality of lower line patterns 122a, the plurality of upper line patterns 122b, and the plurality of pad patterns 123 may be rigid patterns. For example, the plurality of lower plate patterns 121a, the plurality of upper plate patterns 121b, the plurality of lower line patterns 122a, the plurality of upper line patterns 122b, and the plurality of pad patterns 123 may be more rigid than the lower substrate 111 and the upper substrate 112. Accordingly, a modulus of elasticity and hardness of each of the plurality of lower plate patterns 121a, the plurality of upper plate patterns 121b, the plurality of lower line patterns 122a, the plurality of upper line patterns 122b, and the plurality of pad patterns 123 may be higher than a modulus of elasticity and hardness of the lower substrate 111 and the upper substrate 112. For example, the modulus of elasticity of each of the plurality of lower plate patterns 121a, the plurality of upper plate patterns 121b, the plurality of lower line patterns 122a, the plurality of upper line patterns 122b, and the plurality of pad patterns 123 may be 1000 times higher than the modulus of elasticity of the lower substrate 111 and the upper substrate 112. However, this is illustrative and the exemplary embodiment of the present disclosure is not limited thereto.

In one exemplary embodiment, each of the plurality of lower plate patterns 121a, the plurality of upper plate patterns 121b, the plurality of lower line patterns 122a, the plurality of upper line patterns 122b, and the plurality of pad patterns 123 may include a plastic material having a lower flexibility than the lower substrate 111 and the upper substrate 112.

The gate driver GD may supply a gate voltage to the plurality of pixels PX disposed in the active area AA. The gate driver GD may include a plurality of stages formed on the plurality of lower plate patterns 121a disposed in the non-active area NA and each stage included in the gate driver GD may be electrically connected to each other by means of the plurality of gate connection lines. Accordingly, a gate signal output from any one of the stages may be transmitted to the other stage. Each stage may sequentially supply the gate signal to the plurality of pixels PX connected to each stage.

The power supply PS is connected to the gate driver GD to supply a gate driving voltage and a gate clock voltage to the gate driver GD. Further, the power supply PS is connected to the plurality of pixels PX to supply a pixel driving voltage to each of the plurality of pixels PX.

The printed circuit board PCB includes a controller, such as an integrated circuit (IC) chip or a circuit unit and/or a memory or a processor to transmit a signal and a voltage for driving the display element from the controller to the display element. The printed circuit board PCB may include a stretching area and a non-stretching area to ensure stretchability. For example, in the non-stretching area, an IC chip, a circuit unit, a memory, and a processor may be mounted and in the stretching area, wiring lines which are electrically connected to the IC chip, the circuit unit, the memory, and the processor may be disposed.

The driving chip CHIP disposed on the plurality of pad patterns 123 may include a data driver DD. For example, the data driver DD is configured as an IC chip so that it may also be referred to as a data integrated circuit D-IC. The data driver DD may supply a data voltage to the plurality of pixels PX disposed in the active area AA.

Hereinafter, the active area AA of the display device 100 according to the exemplary embodiments of the present disclosure will be described in more detail with reference to FIG. 4 together.

Referring to FIGS. 2 and 4, a pixel PX including the plurality of sub pixels SPX may be disposed in the lower plate pattern 121a disposed on the lower substrate 111. Each of the plurality of sub pixels SPX may include a light emitting diode 170 which is a display element and a driving transistor 160 and a switching transistor 150 which drive the light emitting diode 170. The plurality of sub pixels SPX may include a red sub pixel, a green sub pixel, and a blue sub pixel, but is not limited thereto and colors of the plurality of sub pixels SPX may be modified to various colors as needed.

The sub pixels SPX and the light emitting diode 170 may be connected to a plurality of connection lines 180.

To be more specific, the plurality of sub pixels SPX may be connected to a plurality of lower connection lines 181 and 182. For example, the plurality of sub pixels SPX may be electrically connected to the first lower connection line 181 extending in the first direction X and may be electrically connected to the second lower connection line 182 extending in the second direction Y.

Further, referring to FIGS. 3 and 4, a conductive pattern CPA may be disposed in the upper plate pattern 121b disposed on the upper substrate 112 in the active area AA. The plurality of conductive patterns CPA may be connected to the plurality of upper connection lines 183. The upper connection line 183 extends in the first direction X to be electrically connected to the plurality of conductive patterns CPA.

Referring to FIG. 3, a plurality of light emitting diodes 170 corresponding to the plurality of sub pixels SPX may be disposed on the conductive pattern CPA with respect to the upper substrate 112. The upper substrate 112 on which the plurality of light emitting diodes 170 is disposed may be bonded in the direction of the lower substrate 111. Therefore, the light emitting diode 170 may be bonded to each of the plurality of sub pixels SPX.

Hereinafter, a cross-sectional structure of the active area AA will be described in more detail with reference to FIG. 4.

Referring to FIG. 4, a plurality of inorganic insulating layers may be disposed on the plurality of lower plate patterns 121a disposed in the active area AA. For example, a plurality of inorganic insulating layers may include a buffer layer 141, a gate insulating layer 142, a first interlayer insulating layer 143, a second interlayer insulating layer 144, and a passivation layer 145. However, the exemplary embodiment of the present disclosure is not limited thereto and various inorganic insulating layers are additionally disposed on the plurality of lower plate patterns 121a. At least one of the buffer layer 141, the gate insulating layer 142, the first interlayer insulating layer 143, the second interlayer insulating layer 144, and the passivation layer 145 which are inorganic insulating layers may be omitted.

To be more specific, the buffer layer 141 may be disposed on the plurality of lower plate patterns 121a disposed in the active area AA. The buffer layer 141 includes an insulating material and may be formed on the plurality of lower plate patterns 121a to protect various components of the display device 100 from permeation of moisture (H₂O) and oxygen (O₂) from the outside of the lower substrate 111 and the plurality of lower plate patterns 121a. However, the buffer layer 141 may be omitted depending on a structure or a characteristic of the display device 100.

In one exemplary embodiment, the buffer layer 141 may be formed in an area where the lower substrate 111 overlaps the plurality of lower plate patterns 121a. For example, the buffer layer 141 includes an inorganic material so that the buffer layer 141 may be easily cracked to be damaged during a process of stretching the display device 100. Therefore, the buffer layer 141 is not formed in an area between the plurality of lower plate patterns 121a, but is patterned to have a shape of the plurality of lower plate patterns 121a to be formed only above the plurality of lower plate patterns 121a. Therefore, in the display device 100 according to the exemplary embodiment of the present disclosure, the buffer layer 141 is formed only in an area overlapping the plurality of lower plate patterns 121a which are rigid patterns. Therefore, even though the display device 100 is bent or extended to be deformed, the damage of various components of the display device 100 may be suppressed.

A switching transistor 150 including a gate electrode 151, an active layer 152, a source electrode 153, and a drain electrode 154 and a driving transistor 160 including a gate electrode 161, an active layer 162, a source electrode and a drain electrode 164 may be formed on the buffer layer 141.

First, the active layer 152 of the switching transistor 150 and the active layer 162 of the driving transistor 160 may be disposed on the buffer layer 141. For example, the active layer 152 of the switching transistor 150 and the active layer 162 of the driving transistor 160 may include oxide semiconductor, amorphous silicon (a-Si), polycrystalline silicon (poly-Si), or an organic semiconductor.

The gate insulating layer 142 may be disposed on the active layer 152 of the switching transistor 150 and the active layer 162 of the driving transistor 160. The gate insulating layer 142 includes an insulating material and may electrically insulate the gate electrode 151 of the switching transistor 150 from the active layer 152 of the switching transistor 150 and may electrically insulate the gate electrode 161 of the driving transistor 160 from the active layer 162 of the driving transistor 160.

The gate electrode 151 of the switching transistor 150 and the gate electrode 161 of the driving transistor 160 may be disposed on the gate insulating layer 142. The gate electrode 151 of the switching transistor 150 and the gate electrode 161 of the driving transistor 160 may be disposed on the gate insulating layer 142 to be spaced apart from each other. The gate electrode 151 of the switching transistor 150 may overlap the active layer 152 of the switching transistor 150 and the gate electrode 161 of the driving transistor 160 may overlap the active layer 162 of the driving transistor 160.

The first interlayer insulating layer 143 may be disposed on the gate electrode 151 of the switching transistor 150 and the gate electrode 161 of the driving transistor 160. The first interlayer insulating layer 143 includes an insulating material and may insulate the gate electrode 161 of the driving transistor 160 from an intermediate metal layer IM.

The intermediate metal layer IM may be disposed on the first interlayer insulating layer 143. The intermediate metal layer IM may overlap the gate electrode 161 of the driving transistor 160. Therefore, a capacitor (for example, a storage capacitor) may be formed in an overlapping area of the intermediate metal layer IM and the gate electrode 161 of the driving transistor 160, including a metal material. Specifically, the storage capacitor may be formed by the gate electrode 161 of the driving transistor 160, the first interlayer insulating layer 143, and the intermediate metal layer IM. However, the placement area of the intermediate metal layer IM is not limited thereto and the intermediate metal layer IM overlaps the other electrode to form the storage capacitor in various forms.

The second interlayer insulating layer 144 may be disposed on the intermediate metal layer IM. The second interlayer insulating layer 144 includes an insulating material and may insulate the gate electrode 151 of the switching transistor 150 from the source electrode 153 and the drain electrode 154 of the switching transistor 150. The second interlayer insulating layer 144 may insulate the intermediate metal layer IM from the source electrode and the drain electrode 164 of the driving transistor 160.

The source electrode 153 and the drain electrode 154 of the switching transistor 150 may be disposed on the second interlayer insulating layer 144. The source electrode and the drain electrode 164 of the driving transistor 160 may be disposed on the second interlayer insulating layer 144. The source electrode 153 and the drain electrode 154 of the switching transistor 150 may be disposed on the same layer to be spaced apart from each other. Even though in FIG. 4, the source electrode of the driving transistor 160 is omitted, the source electrode of the driving transistor 160 may also be disposed on the same layer to be spaced apart from the drain electrode 164. In the switching transistor 150, the source electrode 153 and the drain electrode 154 may be in contact with the active layer 152 to be electrically connected to the active layer 152. In the driving transistor 160, the source electrode and the drain electrode 164 may be in contact with the active layer 162 to be electrically connected to the active layer 162. The drain electrode 154 of the switching transistor 150 is in contact with the gate electrode 161 of the driving transistor 160 through a contact hole to be electrically connected to the gate electrode 161 of the driving transistor 160.

A gate pad, a data pad DP, and a voltage pad VP may be disposed on the second interlayer insulating layer 144.

Specifically, the gate pad may be a pad which transmits a gate signal to the plurality of sub pixels SPX. The gate pad may be connected to the first lower connection line 181 through a contact hole. Further, the gate signal supplied from the first lower connection line 181 may be transmitted to the gate electrode 151 of the switching transistor 150 from the gate pad through a wiring line formed on the lower plate pattern 121a.

The data pad DP may be a pad which transmits a data voltage to the plurality of sub pixels SPX. The data pad DP may be connected to the second lower connection line 182 through a contact hole. Further, the data voltage supplied from the second lower connection line 182 may be transmitted to the source electrode 153 of the switching transistor 150 from the data pad DP through a wiring line formed on the lower plate pattern 121a.

A voltage pad VP may be a pad which transmits a high potential voltage to the plurality of sub pixels SPX. The voltage pad VP may be connected to the first lower connection line 181 through a contact hole. Further, a high potential voltage supplied from the first lower connection line 181 may be transmitted to the driving transistor 160 from the voltage pad VP through a wiring line formed on the lower plate pattern 121a. The above-described high potential voltage may be referred to as a second driving voltage and a low potential voltage to be described below may be referred to as a first driving voltage.

The gate pad, the data pad DP, and the voltage pad VP may be formed of the same material as the source electrode 153 and the drain electrodes 154 and 164, but are not limited thereto.

The passivation layer 145 may be disposed on the switching transistor 150 and the driving transistor 160. That is, the passivation layer 145 may be disposed to cover the switching transistor 150 and the driving transistor 160 to protect the switching transistor 150 and the driving transistor 160 from the permeation of moisture and oxygen. The passivation layer 145 may be formed of an inorganic material and configured by a single layer or a double layer, but is not limited thereto.

Further, the gate insulating layer 142, the first interlayer insulating layer 143, the second interlayer insulating layer 144, and the passivation layer 145 are patterned to be formed only in an area overlapping the plurality of lower plate patterns 121a. The gate insulating layer 142, the first interlayer insulating layer 143, the second interlayer insulating layer 144, and the passivation layer 145 include the inorganic material, similar to the buffer layer 141 to be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of lower plate patterns 121a, but are patterned to have a shape of the plurality of lower plate patterns 121a to be formed only above the plurality of lower plate patterns 121a.

The planarization layer 146 may be formed on the passivation layer 145. The planarization layer 146 may planarize upper portions of the switching transistor 150 and the driving transistor 160. The planarization layer 146 may be configured by a single layer or a plurality of layers and may include an organic material.

Referring to FIG. 4, the planarization layer 146 may be disposed so as to cover top surfaces and side surfaces of the buffer layer 141, the gate insulating layer 142, the first interlayer insulating layer 143, the second interlayer insulating layer 144, and the passivation layer 145 on the plurality of lower plate patterns 121a. Further, the planarization layer 146 may enclose the buffer layer 141, the gate insulating layer 142, the first interlayer insulating layer 143, the second interlayer insulating layer 144, and the passivation layer 145 together with the plurality of lower plate patterns 121a. To be more specific, the planarization layer 146 may be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of lower plate patterns 121a. Accordingly, the planarization layer 146 may supplement a step on side surfaces of the buffer layer 141, the gate insulating layer 142, the first interlayer insulating layer 143, the second interlayer insulating layer 144, and the passivation layer 145. Further, the planarization layer 146 may enhance an adhesive strength of the lower connection lines 181 and 182 disposed on a side surface of the planarization layer 146.

In one exemplary embodiment, as illustrated in FIG. 4, an inclination angle of the side surface of the planarization layer 146 may be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 may have a slope which is gentler than a slope each formed by the side surface of the passivation layer 145, the side surface of the first interlayer insulating layer 143, the side surface of the second interlayer insulating layer 144, the side surface of the gate insulating layer 142, and the side surface of the buffer layer 141. Therefore, the lower connection lines 181 and 182 which are disposed to be in contact with the side surface of the planarization layer 146 are disposed with a gentle slope so that when the display device 100 is stretched, the stress generated in the lower connection lines 181 and 182 may be reduced. Further, the side surface of the planarization layer 146 has a relatively gentle slope so that the crack of the lower connection lines 181 and 182 or separation thereof from the side surface of the planarization layer 146 may be suppressed.

Referring to FIGS. 2 to 4, the lower connection lines 181 and 182 may electrically connect the pads on the plurality of lower plate patterns 121a. The lower connection lines 181 and 182 may be disposed on the plurality of lower line patterns 122a. Further, the lower line pattern 122a may not be disposed in an area between the plurality of lower plate patterns 121a in which the lower connection lines 181 and 182 are not disposed.

The lower connection lines 181 and 182 may include a first lower connection line 181 and a second lower connection line 182. The first lower connection line 181 and the second lower connection line 182 include a metal material and may be disposed between the plurality of lower plate patterns 121a. Specifically, the first lower connection line 181 may refer to a wiring line extending in a first direction X between the plurality of lower plate patterns 121a, among the lower connection lines 181 and 182. The second lower connection line 182 may refer to a wiring line extending in a second direction Y between the plurality of lower plate patterns 121a, among the lower connection lines 181 and 182.

In the meantime, in the case of a display panel of a general display device, various wiring lines such as a plurality of gate lines and a plurality of data lines extend between the plurality of sub pixels as a straight line and the plurality of sub pixels is connected to one signal line. Therefore, in the display panel of the general display device, various wiring lines, such as a gate line, a data line, a high potential voltage line, and a reference voltage line, may extend from one side to the other side of the display panel of the organic light emitting display device without being disconnected on the substrate.

In contrast, in the display device 100 according to the exemplary embodiments of the present disclosure, various wiring lines, such as a gate line, a data line, a high potential voltage line, a reference voltage line, or an initialization voltage line having a straight line shape which are considered to be used for the display panel of the general display device, may be disposed only on the plurality of lower plate patterns 121a. That is, in the display device 100 according to the exemplary embodiments of the present disclosure, a linear wiring line may be disposed only on the plurality of lower plate patterns 121a.

In the display device 100 according to the exemplary embodiments of the present disclosure, the pads on two adjacent lower plate patterns 121a may be connected by the lower connection lines 181 and 182. Accordingly, the lower connection lines 181 and 182 may electrically connect the gate pads, the data pads DP, or the voltage pad VP on two adjacent lower plate patterns 121a. Accordingly, the display device 100 according to the exemplary embodiments of the present disclosure may include a plurality of lower connection lines 181 and 182 which electrically connects various wiring lines, such as a gate line, a data line, a high potential voltage line, and a reference voltage line, between the plurality of lower plate patterns 121a. For example, the gate line may be disposed on the plurality of lower plate patterns 121a disposed to be adjacent to each other in the first direction X and the gate pad may be disposed on both ends of the gate line. In this case, the plurality of gate pads on the plurality of lower plate patterns 121a adjacent to each other in the first direction X may be connected to each other by the first lower connection line 181 which serves as a gate line. Therefore, the gate line disposed on the plurality of lower plate patterns 121a and the first lower connection line 181 disposed on the lower line pattern 122a may serve as one gate line. The above-described gate line may be referred to as a scan signal line. Further, wiring lines which extend in the first direction X, among all various wiring lines which may be included in the display device 100, such as an emission signal line and a high potential voltage line, may also be electrically connected by the first lower connection line 181, as described above.

Referring to FIGS. 2 and 4, the first lower connection lines 181 may connect the voltage pads VP on two lower plate patterns 121a which are disposed side by side, among the voltage pads VP on the plurality of lower plate patterns 121a disposed to be adjacent in the first direction X. The first lower connection line 181 may serve as a scan signal line and an emission signal line which are gate lines, but is not limited thereto. The voltage pads VP on the plurality of lower plate patterns 121a disposed in the first direction X may be connected by the first lower connection line 181 serving as a high potential voltage line and transmit one high potential voltage.

Further, the second lower connection line 182 may connect the data pads DP on two lower plate patterns 121a which are disposed side by side, among the data pads DP on the plurality of lower plate patterns 121a disposed to be adjacent in the second direction Y. The second lower connection line 182 may serve as a data line or a reference voltage line, but is not limited thereto. An internal line on the plurality of lower plate patterns 121a disposed in the second direction Y may be connected by the plurality of second lower connection lines 182 serving as data lines and transmit one data voltage.

In one exemplary embodiment, as illustrated in FIG. 4, the first lower connection line 181 may be disposed to be in contact with a top surface and a side surface of the planarization layer 146 disposed on the lower plate pattern 121a. The first lower connection line 181 may be disposed to extend to the top surface of the lower line pattern 122a. Further, the second lower connection line 182 may be disposed to be in contact with a top surface and a side surface of the planarization layer 146 disposed on the lower plate pattern 121a. The second lower connection line 182 may be formed to extend to the top surface of the lower line pattern 122a.

However, there is no need to dispose a rigid pattern in an area in which the first lower connection line 181 and the second lower connection line 182 are not disposed, so that the lower line pattern 122a which is a rigid pattern is not disposed below an area in which the first lower connection line 181 and the second lower connection line 182 are not disposed.

Referring to FIG. 4, a bank 147 may be formed on the connection pad CNT, the lower connection lines 181 and 182, and the planarization layer 146. The bank 147 includes an insulating material and may divide adjacent sub pixels SPX. The bank 147 may be disposed so as to cover at least a part of the connection pad CNT, the lower connection lines 181 and 182, and the planarization layer 146.

Even though in FIG. 4, it is illustrated that a height of the bank 147 is lower than a height of the light emitting diode 170, the present disclosure is not limited thereto and the height of the bank 147 may be substantially equal to the height of the light emitting diode 170.

Referring to FIG. 4, the light emitting diode 170 may be disposed on the connection pad CNT and the first lower connection line 181. The light emitting diode 170 may include a first electrode 171, a first semiconductor pattern 172, an emission layer 173, a second semiconductor pattern 174, and a second electrode 175. For example, the first semiconductor pattern 172, the emission layer 173, the second semiconductor pattern 174, and the second electrode 175 may be sequentially disposed on the first electrode 171. Therefore, the light emitting diode 170 may be a vertical light emitting diode in which the second electrode 175 is disposed on the first electrode 171.

Further, the first semiconductor pattern 172 may be disposed on the first adhesive pattern AD1 and the second semiconductor pattern 174 may be disposed on the first semiconductor pattern 172. The first semiconductor pattern 172 and the second semiconductor pattern 174 may be layers formed by doping n-type and p-type impurities into a specific material.

The emission layer 173 may be disposed between the first semiconductor pattern 172 and the second semiconductor pattern 174. The emission layer 173 is supplied with holes and electrons from the first semiconductor pattern 172 and the second semiconductor pattern 174 to emit light.

The first electrode 171 may be disposed below the first semiconductor pattern 172. The first electrode 171 may be disposed on the bottom surface of the first semiconductor pattern 172. The first electrode 171 includes a conductive material and may electrically connect the driving transistor 160 and the first semiconductor pattern 172.

The second electrode 175 may be disposed on the second semiconductor pattern 174. The second electrode 175 may be disposed on the top surface of the second semiconductor pattern 174. The second electrode 175 includes a conductive material and may electrically connect the conductive pattern CPA and the second semiconductor pattern 174.

The first adhesive pattern AD1 is disposed between the connection pad CNT and the first electrode 171 so that the light emitting diode 170 may be bonded onto the connection pad CNT. The second adhesive pattern AD2 is disposed between the conductive pattern CPA and the second electrode 175 so that the light emitting diode 170 may be bonded below the conductive pattern CPA.

The connection pad CNT is electrically connected to the drain electrode 164 of the driving transistor 160 to be applied with a driving voltage from the driving transistor 160 to drive the light emitting diode 170. In the meantime, even though in FIG. 4, it is illustrated that the connection pad CNT is not in direct contact with the drain electrode 164 of the driving transistor 160, but is in indirect contact therewith, the present disclosure is not limited thereto. Therefore, the connection pad CNT and the drain electrode 164 of the driving transistor 160 may be in direct contact with each other. In addition, a low potential voltage may be applied to the first lower connection line 181 to drive the light emitting diode 170.

Referring to FIGS. 3 and 4, with respect to the upper substrate 112, the plurality of upper plate patterns 121b and the plurality of upper line patterns 122b which connects the plurality of upper plate patterns 121b may be disposed on the upper substrate 112. In other words, with respect to the lower substrate 111, the plurality of upper plate patterns 121b and the plurality of upper line patterns 122b which connects the plurality of upper plate patterns 121b may be disposed below the upper substrate 112. That is, the plurality of upper plate patterns 121b and the plurality of upper line patterns 122b may be disposed to be in contact with the upper substrate 112.

Specifically, the plurality of upper line patterns 122b disposed in the active area AA may connect upper plate patterns 121b which are disposed to be adjacent to each other in the first direction X. Therefore, the plurality of upper line patterns 122b may extend in the first direction X. However, it is not limited thereto and the plurality of upper line patterns 122b may extend to the first direction X or to the first direction X and the second direction Y, respectively.

Further, with respect to the upper substrate 112, the conductive pattern CPA may be disposed on the upper plate pattern 121b disposed in the active area AA and the upper connection line 183 may be disposed on the upper line pattern 122b disposed in the active area AA. In other words, with respect to the lower substrate 111, the conductive pattern CPA may be disposed below the upper plate pattern 121b disposed in the active area AA and the upper connection line 183 may be disposed below the upper line pattern 122b disposed in the active area AA.

The conductive pattern CPA disposed in the active area AA may have the same shape as the upper plate pattern 121b. For example, the upper plate pattern 121b has island shapes which are spaced apart from each other so that the conductive patterns CPA may also have island shapes which are spaced apart from each other.

The upper connection line 183 may have the same shape as the upper line pattern 122b. For example, the upper connection line 183 may have a sine wave shape, which is just illustrative. Therefore, the plurality of upper line patterns 122b and the plurality of upper connection lines 183 may extend in a zigzag shape or have various shapes such as a plurality of rhombic substrates which is connected at their vertices to be extended.

According to the exemplary embodiment, the plurality of conductive patterns CPA and the plurality of upper connection lines 183 may be integrally formed. For example, the plurality of conductive patterns CPA and the plurality of upper connection lines 183 may be simultaneously formed by the same process. However, it is not limited thereto and the plurality of conductive patterns CPA and the plurality of upper connection lines 183 may be separately formed.

A low potential voltage for driving the light emitting diode 170 may be applied to the plurality of conductive patterns CPA and the plurality of upper connection lines 183. That is, the plurality of conductive patterns CPA and the plurality of upper connection lines 183 may configure a conductive surface to which one low potential voltage is applied.

Therefore, when the display device 100 is on, the driving voltage may be applied to the first electrode 171 by means of the connection pad CNT and the low potential voltage may be applied to the second electrode by means of the conductive pattern CPA. Therefore, different voltage levels are transmitted to the first electrode 171 and the second electrode 175, respectively, to allow the light emitting diode 170 to emit light.

The filling layer 190 may be further disposed on the entire surface of the lower substrate 111 to fill between the components disposed on the upper substrate 112 and the components disposed on the lower substrate 111. The filling layer 190 may be configured by a curable adhesive. Specifically, the material which configures the filling layer 190 is coated on the entire surface of the lower substrate 111 and then is cured so that the filling layer 190 may be disposed between the components disposed on the upper substrate 112 and the components disposed on the lower substrate 111.

As described above, the display device 100 according to the exemplary embodiments of the present disclosure may supply a low potential voltage to the light emitting diode by means of the upper connection line 183 and the conductive pattern CPA attached to the upper substrate 112. Further, a total area of the upper connection line 183 and the conductive pattern CPA is larger than a total area of the lower connection lines 181 and 182 so that a total resistance of the upper connection line 183 and the conductive pattern CPA may be relatively low. Therefore, the voltage drop of the low potential voltage which is supplied through the upper connection line 183 and the conductive pattern CPA may be suppressed. Accordingly, a stable low potential voltage may be supplied to the light emitting diode 170. As a result, the display device 100 according to the exemplary embodiments of the present disclosure may ensure a luminous efficiency and a stability of the light emitting diode 170 to improve an image quality.

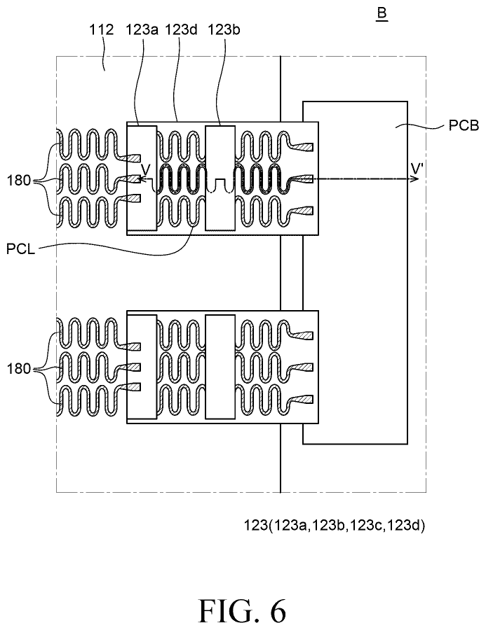

FIGS. 5 and 6 are enlarged plan views illustrating an example of a part B of FIG. 1 according to exemplary embodiments of the present disclosure.

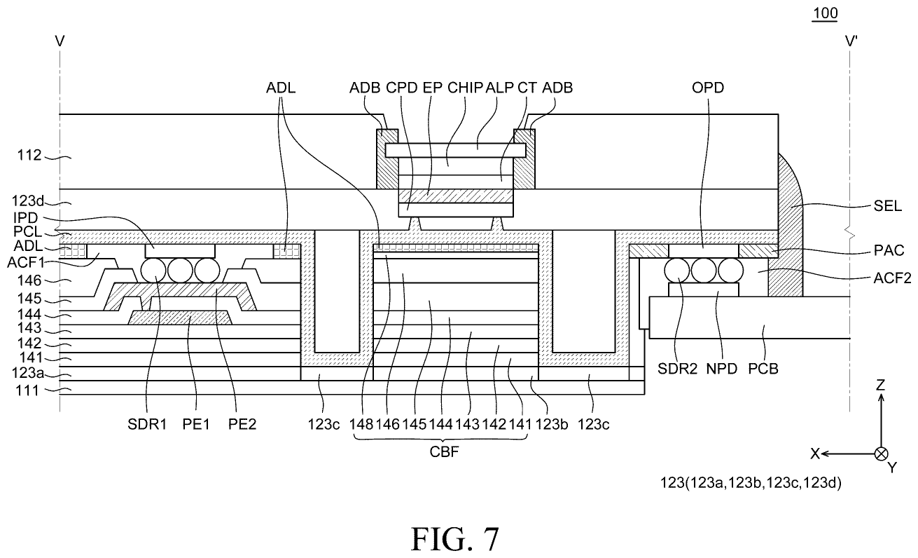

FIG. 7 is a cross-sectional view illustrating an example taken along the line V-V′ of FIGS. 5 and 6 according to exemplary embodiments of the present disclosure.

In the meantime, in FIG. 5, among components of the display device 100 according to exemplary embodiments, a lower substrate 111 and components disposed on the lower substrate 111 for the part B of FIG. 1 are illustrated. In FIG. 6, among components of the display device 100 according to exemplary embodiments, an upper substrate 112 and components disposed on the upper substrate 112 for the part B of FIG. 1 are illustrated.

Referring to FIGS. 1, 5, and 6, each of the plurality of pad patterns 123 may be disposed between the lower substrate 111 and the upper substrate 112. Each of the plurality of pad patterns 123 may be disposed in the non-active area NA of the lower substrate 111 and the upper substrate 112. For example, the plurality of pad patterns 123 may be disposed in the non-active area NA between the active area AA and the printed circuit board PCB.

Referring to FIGS. 1, 5, 6, and 7, a driving chip CHIP and a plurality of pads (for example, an input pad IPD, an output pad OPD, a connection pad NPD, and a chip pad CPD) connected thereto may be disposed on the plurality of pad patterns 123.

To be more specific, referring to FIGS. 5 and 6, each of the plurality of pad patterns 123 may include a plurality of lower pad plate patterns 123a and 123b, a plurality of lower pad line patterns 123c which connects the plurality of lower pad plate patterns 123a and 123b, and a plurality of upper pad plate patterns 123d. The plurality of upper pad plate patterns 123d is disposed on the plurality of lower pad plate patterns 123a and 123b and the plurality of lower pad line patterns 123c.

Each of the plurality of lower pad plate patterns 123a and 123b extends along the second direction Y and may be disposed to be spaced apart from each other along the first direction X. For example, as illustrated in FIG. 6, each of the plurality of lower pad plate patterns 123a and 123b may have a rectangular shape including one pair of long sides extending along the second direction Y and one pair of short sides extending along the first direction X. However, the shape of the plurality of lower pad plate patterns 123a and 123b is not limited thereto.

Further, the upper pad plate pattern 123d has a shape extending along the first direction X and may be disposed to cover the plurality of lower pad plate patterns 123a and 123b and the lower pad line pattern 123c disposed there below. For example, as illustrated in FIGS. 5 and 6, the upper pad plate pattern 123d is disposed on the plurality of lower pad plate patterns 123a and 123b and the lower pad line pattern 123c. In the plan view, the upper pad plate pattern 123d overlaps all the plurality of lower pad plate patterns 123a and 123b and the lower pad line pattern 123c and may be disposed to cover the plurality of lower pad plate patterns 123a and 123b and the lower pad line pattern 123c. Accordingly, the upper pad plate pattern 123d may have a rectangular shape having an area larger than that of the plurality of lower pad plate patterns 123a and 123b disposed there below. For example, as illustrated in FIGS. 5 and 6, the upper pad plate pattern 123d may have a rectangular shape including one pair of long sides extending along the first direction X and one pair of short sides extending along the second direction Y. However, the shape of the upper pad plate pattern 123d is not limited thereto.

Further referring to FIG. 7, a plurality of pad electrodes PE1 and PE2 and an input pad IPD may be disposed on the first lower pad plate pattern 123a and a chip pad CPD and a driving chip CHIP may be disposed on the second lower pad plate pattern 123b.

To be more specific, a plurality of pad electrodes PE1 and PE2 and an input pad IPD may be disposed between the first lower pad plate pattern 123a and the upper pad plate pattern 123d. The plurality of pad electrodes PE1 and PE2 disposed on the first lower pad plate pattern 123a is connected to the plurality of connection lines 180 to be connected to the plurality of pixels PX disposed in the active area AA and/or the gate driver GD and the power supply PS disposed in the non-active area NA. Further, a first conductive film ACF1 is disposed between the plurality of pad electrodes PE1 and PE2 and the input pad IPD disposed on the first lower pad plate pattern 123a so that the plurality of pad electrodes PE1 and PE2 and the input pad IPD may be electrically connected. Further, the pad connection line PCL is disposed between the input pad IPD and the upper pad plate pattern 123d disposed on the first lower pad plate pattern 123a so that the input pad IPD may be connected to the pad connection line PCL. In other words, the pad connection line PCL is disposed on the upper pad plate pattern 123d with respect to the upper substrate 112 to be connected to the input pad IPD disposed on the first lower pad plate pattern 123a with respect to the lower substrate 111.

In one exemplary embodiment, referring to FIG. 6, the pad connection line PCL may have a wavy shape. For example, the pad connection line PCL is disposed so as to be in contact with the upper pad plate pattern 123d in an area overlapping the plurality of lower pad plate patterns 123a and 123b. Further, the pad connection line PCL may be disposed so as to be in contact with the lower pad line pattern 123c on the lower pad line pattern 123c in an area overlapping the plurality of lower pad line patterns 123c. Accordingly, the pad connection line PCL may have a shape corresponding to the lower pad line pattern 123c. For example, the pad connection line PCL may have a sine wave shape. However, it is just illustrative, so that the shape of the pad connection line PCL is not limited thereto. For example, the pad connection line PCL may have a zigzag shape. As another example, the pad connection line PCL may have various shapes, such as a plurality of rhombic substrates being connected and extending at their vertices.

As described above, the driving chip CHIP and the plurality of pads IPD, CPD, OPD, and NPD connected thereto are disposed on the plurality of pad patterns 123. The plurality of pad patterns 123 include a lower pad line pattern 123c which has the pad connection line PCL disposed therein and has a wavy shape. Therefore, in the display device 100 according to the exemplary embodiments of the present disclosure, an area (for example, a pad area) in which the driving chip CHIP and the plurality of pads IPD, CPD, OPD, and NPD connected thereto are disposed may also be stretchable.

The pad connection line PCL may include a metal material, such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

Further, the chip pad CPD and the driving chip CHIP may be disposed on the second lower pad plate pattern 123b and the upper pad plate pattern 123d. That is, with respect to the lower substrate 111, the upper pad plate pattern 123d may be disposed on the second lower pad plate pattern 123b and the chip pad CPD and the driving chip CHIP may be disposed on the upper pad plate pattern 123d. The electrode pattern EP and the connection electrode CT are disposed between the chip pad CPD and the driving chip CHIP disposed on the second lower pad plate pattern 123b and the upper pad plate pattern 123d so that the chip pad CPD and the driving chip CHIP may be electrically connected. Further, the pad connection line PCL also extends between the upper pad plate pattern 123d and the second lower pad plate pattern 123b to be connected to the chip pad CPD. In other words, the pad connection line PCL extends from an area overlapping the first lower pad plate pattern 123a to the lower pad line pattern 123c on the upper pad plate pattern 123d with respect to the upper substrate 112. Further, the pad connection line PCL extends from the lower pad line pattern 123c to an area overlapping the second lower pad plate pattern 123b to be connected to the chip pad CPD and the driving chip CHIP.

Further, the output pad OPD and the connection pad NPD may be disposed on the upper pad plate pattern 123d in which the plurality of lower pad plate patterns 123a and 123b is not disposed, among the upper pad plate patterns 123d, with respect to the upper substrate 112. That is, the output pad OPD and the connection pad NPD may not overlap the plurality of lower pad plate patterns 123a and 123b. For example, the output pad OPD and the connection pad NPD may be disposed on the upper pad plate pattern 123d with respect to the upper substrate 112, so as to correspond to the outermost area of the display device 100 in which the printed circuit board PCB is disposed. A second conductive film ACF2 is disposed between the output pad OPD and the connection pad NPD disposed on the upper pad plate pattern 123d so that the output pad OPD and the connection pad NPD may be electrically connected.

Further, the pad connection line PCL also extends between the output pad OPD and the upper pad plate pattern 123d so that the output pad OPD may be connected to the pad connection line PCL and the connection pad NPD may be connected to the printed circuit board PCB. Accordingly, the plurality of pad electrodes PE1 and PE2, the input pad IPD, the chip pad CPD, and the driving chip CHIP are connected to the output pad OPD and the connection pad NPD through the pad connection line PCL. Therefore, the plurality of pads IPD, CPD, OPD, and NPD and the driving chip CHIP may be electrically connected to the printed circuit board PCB.

Hereinafter, referring to FIG. 7, a cross-sectional structure of the non-active area NA, for example, a cross-sectional structure of the non-active area NA in which the driving chip CHIP is disposed will be described in more detail.

In the meantime, for the convenience of description, a description repeated with the cross-sectional structure of the display device 100 which has been described with reference to FIG. 4 will not be repeated.

Referring to FIG. 7, a plurality of inorganic insulating layers may be disposed on a first lower pad plate pattern 123a. For example, the plurality of inorganic insulating layers may include a buffer layer 141, a gate insulating layer 142, a first interlayer insulating layer 143, a second interlayer insulating layer 144, a passivation layer 145, and a planarization layer 146. For example, the buffer layer 141, the gate insulating layer 142, the first interlayer insulating layer 143, the second interlayer insulating layer 144, the passivation layer 145, and the planarization layer 146 may be sequentially disposed on the first lower pad plate patterns 123a. However, the exemplary embodiment of the present disclosure is not limited thereto and various inorganic insulating layers are additionally disposed on the first lower pad plate pattern 123a. Alternatively, at least one of the buffer layer 141, the gate insulating layer 142, the first interlayer insulating layer 143, the second interlayer insulating layer 144, the passivation layer 145, and the planarization layer 146 which are inorganic insulating layers may be omitted.

In one exemplary embodiment, the buffer layer 141, the gate insulating layer 142, the first interlayer insulating layer 143, the second interlayer insulating layer 144, the passivation layer 145, and the planarization layer 146 may be formed only in an area overlapping the first lower pad plate patterns 123a. For example, as described above, the buffer layer 141, the gate insulating layer 142, the first interlayer insulating layer 143, the second interlayer insulating layer 144, the passivation layer 145, and the planarization layer 146 include the inorganic material, to be easily cracked to be damaged during the process of stretching the display device 100. Therefore, the buffer layer 141, the gate insulating layer 142, the first interlayer insulating layer 143, the second interlayer insulating layer 144, the passivation layer 145, and the planarization layer 146 are not formed in an area in which the first lower pad plate pattern 123a is not disposed, but are patterned to have a shape of the first lower pad plate pattern 123a to be formed only above the first lower pad plate pattern 123a. Therefore, in the display device 100 according to the exemplary embodiment of the present disclosure, the buffer layer 141, the gate insulating layer 142, the first interlayer insulating layer 143, the second interlayer insulating layer 144, the passivation layer 145, and the planarization layer 146 is formed in an area overlapping the first lower pad plate pattern 123a which is a rigid pattern. Therefore, even though the display device 100 is bent or extended to be deformed, the damage of various components of the display device 100 may be suppressed.

The first pad electrode PE1 may be disposed between the first interlayer insulating layer 143 and the second interlayer insulating layer 144 disposed on the first lower pad plate pattern 123a. For example, the first pad electrode PE1 may be disposed on the first interlayer insulating layer 143 and the second interlayer insulating layer 144 may be disposed on the first interlayer insulating layer 143 so as to cover the first pad electrode PE1.

The first pad electrode PE1 may include a metal material. For example, the first pad electrode PE1 may include any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but the material of the first pad electrode PE1 is not limited thereto.

In one exemplary embodiment, the first pad electrode PE1 disposed on the first interlayer insulating layer 143 on the first lower pad plate pattern 123a may include the same material as the intermediate metal layer IM disposed on the first interlayer insulating layer 143 on the plurality of lower plate patterns 121a disposed in the active area AA. For example, the first pad electrode PE1 disposed on the first interlayer insulating layer 143 on the first lower pad plate pattern 123a and the intermediate metal layer IM disposed on the first interlayer insulating layer 143 on the plurality of lower plate patterns 121a disposed in the active area AA may be simultaneously formed by the same process. However, the present disclosure is not limited thereto.

The second pad electrode PE2 may be disposed between the second interlayer insulating layer 144 and the passivation layer 145 disposed on the first lower pad plate pattern 123a. For example, the second pad electrode PE2 may be disposed on the second interlayer insulating layer 144 and the passivation layer 145 may be disposed on the second interlayer insulating layer 144 so as to cover at least a part of the second pad electrode PE2. For example, the passivation layer 145 is disposed on the second pad electrode PE2 and may be patterned so as to expose a part of the second pad electrode PE2. In the meantime, the planarization layer 146 disposed on the passivation layer 145 is also disposed to cover at least a part of the second pad electrode PE2 to be patterned to expose the part of the second pad electrode PE2.

The second pad electrode PE2 may include a metal material. For example, the second pad electrode PE2 may include any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but the material of the second pad electrode PE2 is not limited thereto.

In one exemplary embodiment, the second pad electrode PE2 disposed on the second interlayer insulating layer 144 on the first lower pad plate pattern 123a may include the same material as the source electrode 153 and the drain electrodes 154 and 164 disposed on the second interlayer insulating layer 144 on the plurality of lower plate patterns 121a disposed in the active area AA. For example, the second pad electrode PE2 disposed on the second interlayer insulating layer 144 on the first lower pad plate pattern 123a and the source electrode 153 and the drain electrodes 154 and 164 disposed on the second interlayer insulating layer 144 on the plurality of lower plate patterns 121a disposed in the active area AA may be simultaneously formed by the same process. However, the exemplary embodiment of the present disclosure is not limited thereto.

Further, the second pad electrode PE2 may be electrically connected to the first pad electrode PE1 through a contact hole which passes through the second interlayer insulating layer 144.

In the meantime, in FIG. 7, it is described that a plurality of pad electrodes PE1 and PE2 are formed on different layers, the exemplary embodiment of the present disclosure is not limited thereto. For example, according to the exemplary embodiment, only one pad electrode, for example, the second pad electrode PE2 may also be formed on the second interlayer insulating layer 144.

The input pad IPD is disposed on the second pad electrode PE2, the first conductive film ACF1 is disposed between the second pad electrode PE2 and the input pad IPD to electrically connect the second pad electrode PE2 and the input pad IPD. For example, the first conductive film ACF1 is an anisotropic conductive film and may include a first conductive ball SDR1, but is not limited thereto and the second pad electrode PE2 and the input pad IPD may be connected through a conductive adhesive member, such as anisotropic conductive paste.

Further, as described above, the pad connection line PCL is disposed between the input pad IPD and the upper pad plate pattern 123d disposed on the first lower pad plate pattern 123a so that the input pad IPD may be connected to the pad connection line PCL.

According to the exemplary embodiment, the pad connection line PCL may be bonded to configurations disposed there below by the first conductive film ACF1 and the adhesive layer ADL. For example, the first conductive film ACF1 and the adhesive layer ADL may be disposed between the pad connection line PCL and the configurations (for example, the planarization layer 146, the passivation layer 145, and the second pad electrode PE2) disposed below the pad connection line PCL. In the meantime, in the case of the display device 100 according to the exemplary embodiment of the present disclosure, not only the first conductive film ACF1, but also the adhesive layer ADL are additionally formed to improve the adhesive strength between the pad connection line PCL and the configurations disposed below the pad connection line PCL.

A chip buffer unit CBF including a plurality of inorganic insulating layers may be disposed on the second lower pad plate pattern 123b. For example, the plurality of inorganic insulating layers included in the chip buffer unit CBF may include a buffer layer 141, a gate insulating layer 142, a first interlayer insulating layer 143, a second interlayer insulating layer 144, a passivation layer 145, and a planarization layer 146. For example, the buffer layer 141, the gate insulating layer 142, the first interlayer insulating layer 143, the second interlayer insulating layer 144, the passivation layer 145, and the planarization layer 146 may be sequentially disposed on the second lower pad plate patterns 123b. However, the exemplary embodiment of the present disclosure is not limited thereto and various inorganic insulating layers are additionally disposed on the second lower pad plate pattern 123b. Alternatively, at least one of the buffer layer 141, the gate insulating layer 142, the first interlayer insulating layer 143, the second interlayer insulating layer 144, the passivation layer 145, and the planarization layer 146 which are inorganic insulating layers may be omitted.

Further, the chip buffer unit CBF disposed on the second lower pad plate pattern 123b may further include an overcoat layer 148 disposed on the planarization layer 146. The overcoat layer 148 removes a step caused by a lower film and may have a substantially flat top surface.

The overcoat layer 148 may include an organic material. For example, the overcoat layer 148 may be formed of an acrylic organic material, but is not limited thereto.

In one exemplary embodiment, the buffer layer 141, the gate insulating layer 142, the first interlayer insulating layer 143, the second interlayer insulating layer 144, the passivation layer 145, the planarization layer 146, and the overcoat layer 148 included in the chip buffer unit CBF may be formed only in an area overlapping the second lower pad plate patterns 123b. For example, as described above, the buffer layer 141, the gate insulating layer 142, the first interlayer insulating layer 143, the second interlayer insulating layer 144, the passivation layer 145, the planarization layer 146, and the overcoat layer 148 included in the chip buffer unit CBF include the inorganic material, to be easily cracked to be damaged during the process of stretching the display device 100. Therefore, the buffer layer 141, the gate insulating layer 142, the first interlayer insulating layer 143, the second interlayer insulating layer 144, the passivation layer 145, the planarization layer 146, and the overcoat layer 148 included in the chip buffer unit CBF are not formed in an area in which the second lower pad plate pattern 123b is not disposed, but are patterned to have a shape of the second lower pad plate pattern 123b to be formed only above the second lower pad plate pattern 123b. Therefore, the display device 100 according to the exemplary embodiment of the present disclosure forms the buffer layer 141, the gate insulating layer 142, the first interlayer insulating layer 143, the second interlayer insulating layer 144, the passivation layer 145, the planarization layer 146, and the overcoat layer 148 included in the chip buffer unit CBF only in an area which overlaps the second lower pad plate pattern 123b which is a rigid pattern. Therefore, damages of various components of the display device 100 may be suppressed even though the display device 100 is bent or stretched.

Further, as described above, the pad connection line PCL may also extend between the upper pad plate pattern 123d and the second lower pad plate pattern 123b. For example, the pad connection line PCL may be disposed between the upper pad plate pattern 123d and the input pad IPD in an area overlapping the first lower pad plate pattern 123a, and extend from the area overlapping the first lower pad plate pattern 123a onto the plurality of lower pad line patterns 123c. Further, the pad connection line PCL may extend between the upper pad plate pattern 123d and the chip buffer unit CBF in an area overlapping the second lower pad plate pattern 123b. The pad connection line PCL may be connected to the chip pad CPD. For example, the pad connection line PCL may be connected to the chip pad CPD through a contact hole which passes through the upper pad plate pattern 123d.

According to the exemplary embodiment, the pad connection line PCL may be bonded to the chip buffer unit CBF disposed there below, for example, the overcoat layer 148, by means of the adhesive layer ADL. For example, the adhesive layer ADL may be disposed between the pad connection line PCL and the chip buffer unit CBF. Therefore, the pad connection line PCL and the chip buffer unit CBF may be bonded.

Further, with respect to the lower substrate 111, the chip pad CPD and the driving chip CHIP may be disposed on an upper pad plate pattern 123d overlapping the second lower pad plate pattern 123b, among the upper pad plate patterns 123d. Further, as described above, the electrode pattern EP and the connection electrode CT are disposed between the chip pad CPD and the driving chip CHIP so that the chip pad CPD and the driving chip CHIP may be electrically connected. For example, the connection electrode CT including a metal material is disposed on the chip pad CPD to be electrically connected to the chip pad CPD and the chip pad CPD and the driving chip CHIP may be bonded by the connection electrode CT formed by a soldering process.

According to the exemplary embodiment, as illustrated in FIG. 7, the chip pad CPD and the electrode pattern EP may be disposed in a part obtained by removing at least a part of the upper pad plate pattern 123d, but the exemplary embodiment of the present disclosure is not limited thereto.

A heat dissipation plate ALP may be disposed above the driving chip CHIP. The heat dissipation plate ALP may release heat generated in the driving chip CHIP to the outside. For example, the heat dissipation plate ALP may include a material which easily releases heat. For example, the heat dissipation plate ALP is formed of metal, such as aluminum (Al), which is easy to be manufactured by a sheet metal processing, to quickly dissipate heat generated in the driving chip CHIP to the outside. Further, the heat dissipation plate ALP is disposed above the driving chip CHIP to suppress a damage applied to the driving chip CHIP disposed therebelow.

According to the exemplary embodiment, the driving chip CHIP may be fixed onto the upper pad plate pattern 123d by the adhesive member ADB. For example, the adhesive member ADB may be an optically clear adhesive film or an optically clear adhesive resin.

Further, the upper substrate 112 may be disposed on the upper pad plate pattern 123d. According to the exemplary embodiment, at least a part of the upper substrate 112, for example, a part of an area of the upper substrate 112 in which the driving chip CHIP is disposed is removed to be patterned. For example, the upper substrate 112 may include an opening which exposes at least a part of a top surface of the heat dissipation plate ALP disposed on the driving chip CHIP. Accordingly, the heat dissipation plate ALP disposed on the driving chip CHIP is exposed so that the heat generated by the driving chip CHIP may be effectively released by the heat dissipation plate ALP.

Further, the output pad OPD and the connection pad NPD may be disposed on the upper pad plate pattern 123d in which the plurality of lower pad plate patterns 123a and 123b is not disposed, among the upper pad plate patterns 123d, with respect to the upper substrate 112. For example, the output pad OPD and the connection pad NPD may be disposed on the upper pad plate pattern 123d with respect to the upper substrate 112, so as to correspond to the outermost area of the display device 100 in which the printed circuit board PCB is disposed. In other words, in an area overlapping an area in which the printed circuit board PCB is disposed, the output pad OPD and the connection pad NPD may be disposed below the upper pad plate pattern 123d.

Further, the pad connection line PCL also extends between the output pad OPD and the upper pad plate pattern 123d so that the output pad OPD may be connected to the pad connection line PCL.

Further, the second conductive film ACF2 is disposed between the output pad OPD and the connection pad NPD so that the output pad OPD and the connection pad NPD may be electrically connected. For example, the second conductive film ACF2 is an anisotropic conductive film and may include a second conductive ball SDR2, but is not limited thereto and the output pad OPD and the connection pad NPD may be connected through a conductive adhesive member, such as anisotropic conductive paste.

Further, the connection pad NPD may be connected to the printed circuit board PCB.

Accordingly, all the plurality of pad electrodes PE1 and PE2, the input pad IPD, the chip pad CPD, and the driving chip CHIP are connected to the output pad OPD and the connection pad NPD through the pad connection line PCL. Therefore, the plurality of pads IPD, CPD, OPD, and NPD and the driving chip CHIP may be electrically connected to the printed circuit board PCB.

In the meantime, the output pad OPD may be attached below the upper pad plate pattern 123d by a bonding buffer PAC. For example, the output pad OPD may be attached below the upper pad plate pattern 123d by a TAB bonding (tape automated bonding) method which seals both side surfaces of the output pad OPD with a sealant. For example, the bonding buffer PAC may include photo acryl, but is not limited thereto.

In the meantime, a sealant SEL is disposed at the outermost periphery of the display device 100 so that the outermost periphery of the display device 100 may be sealed by the sealant SEL.

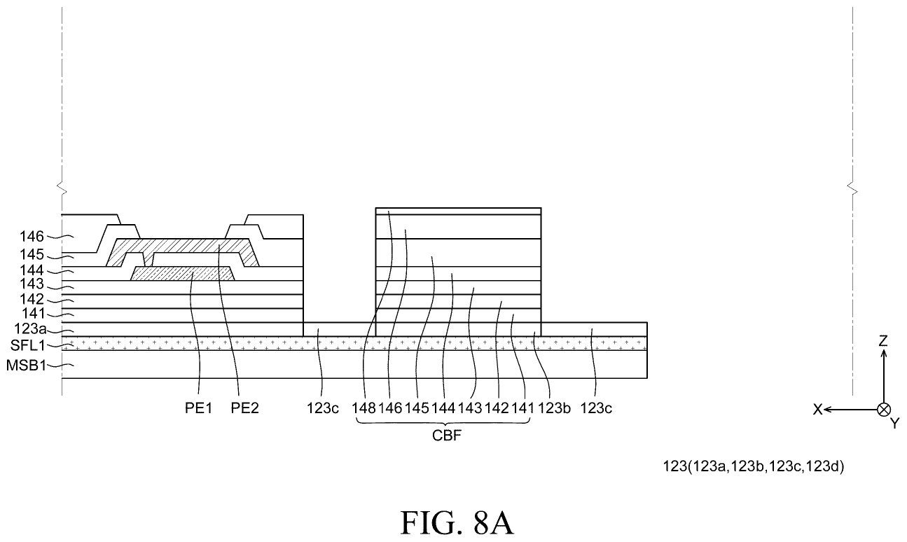

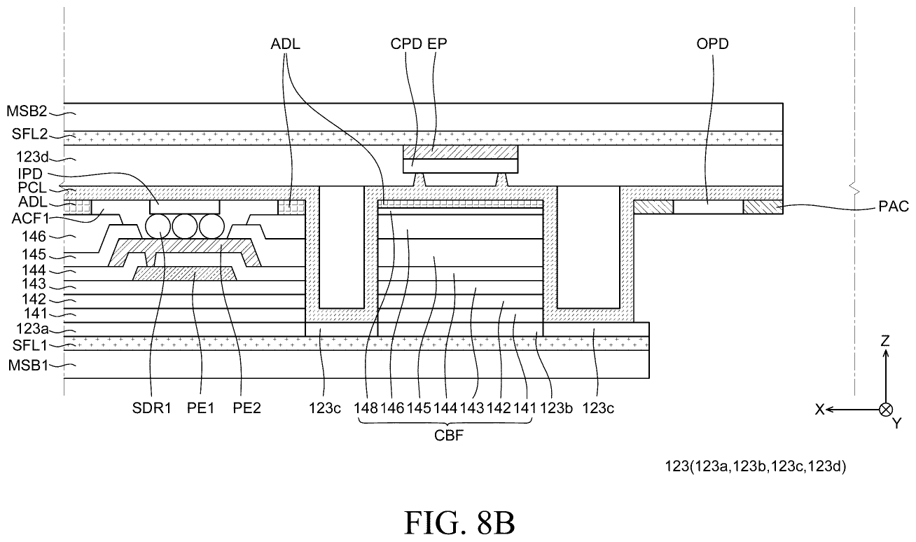

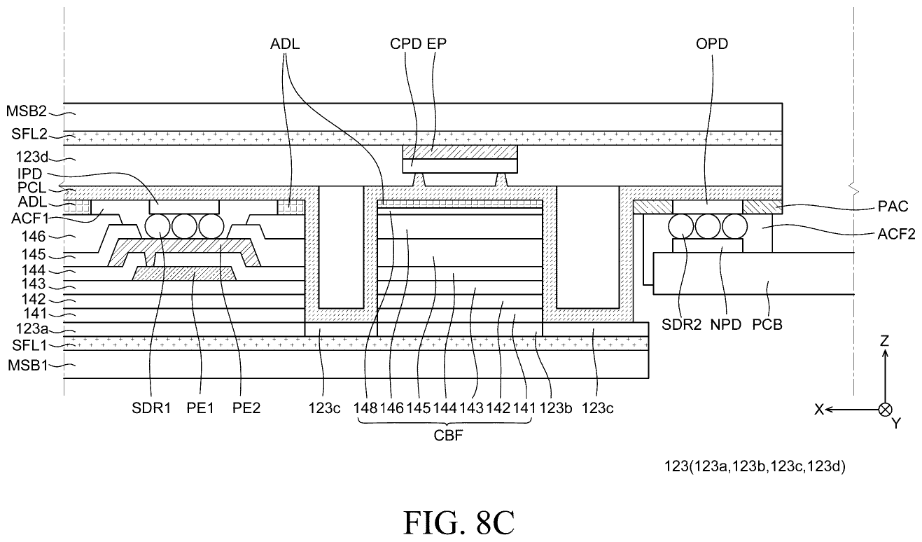

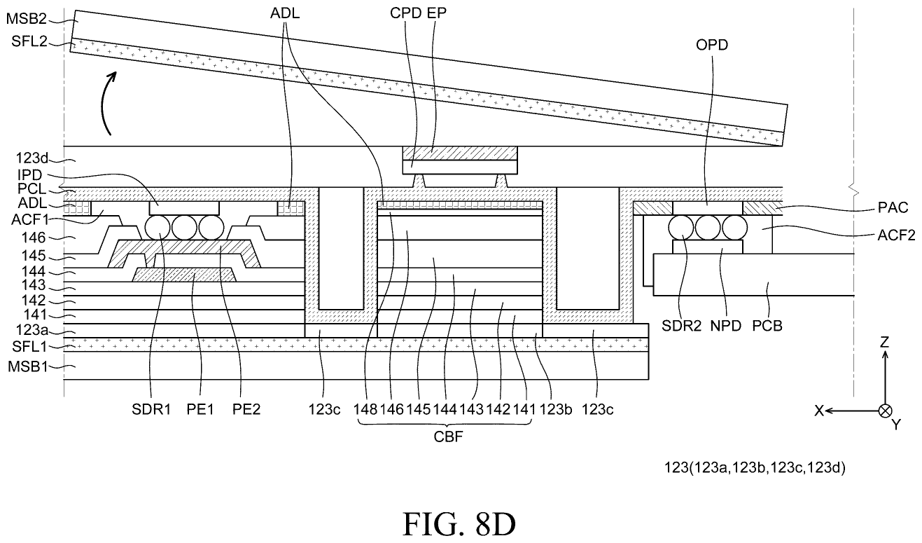

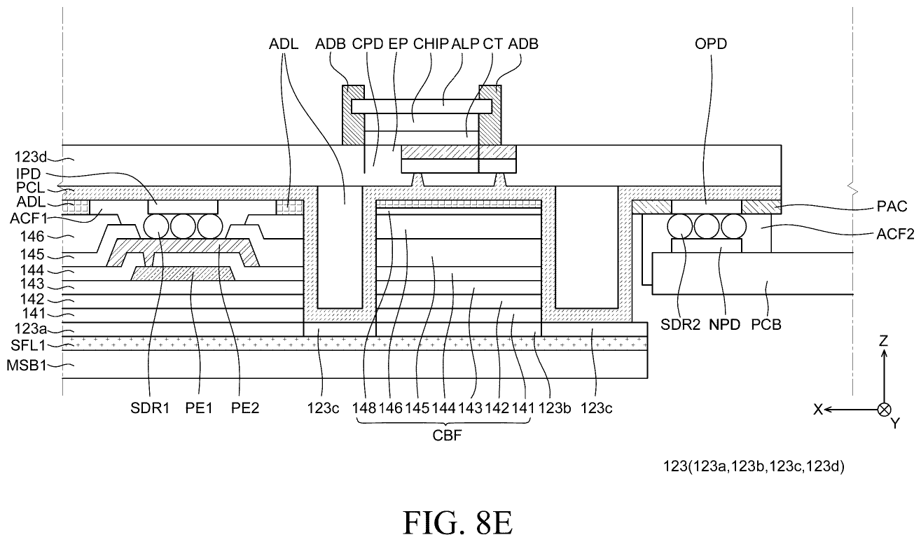

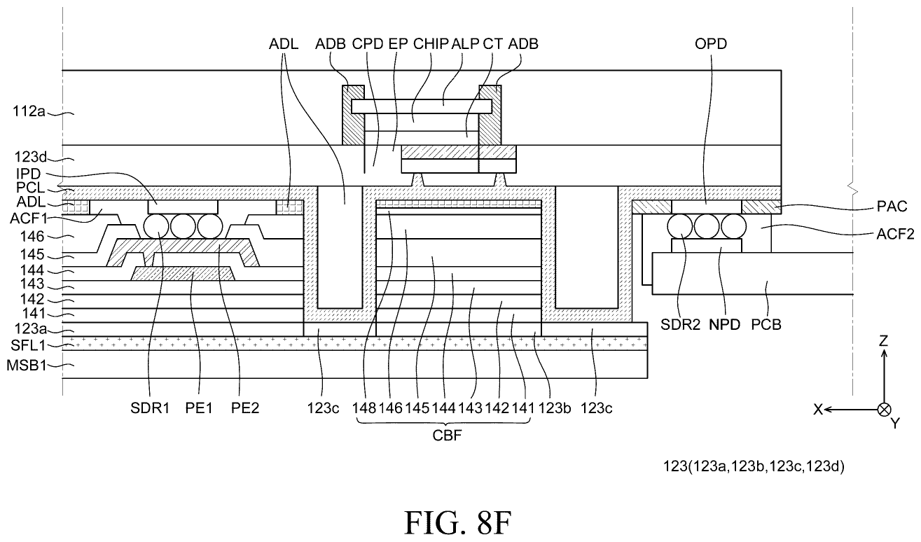

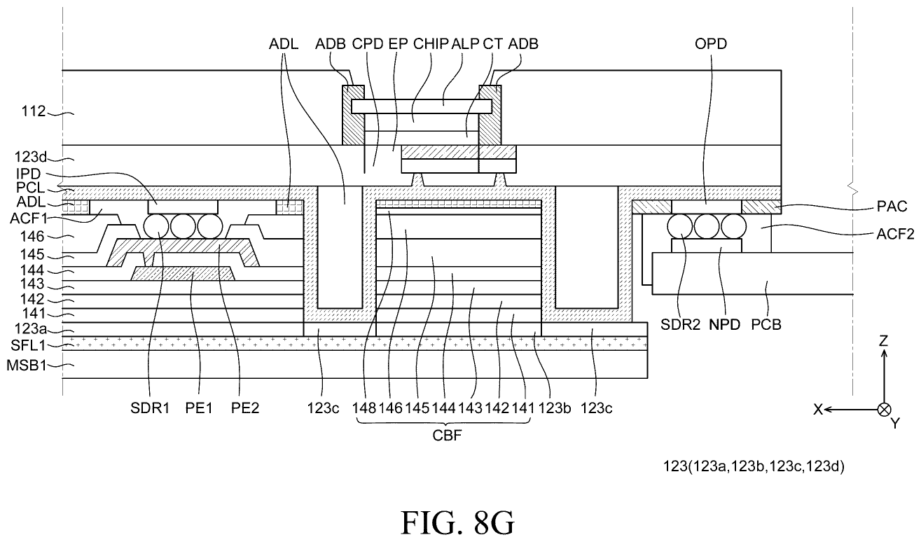

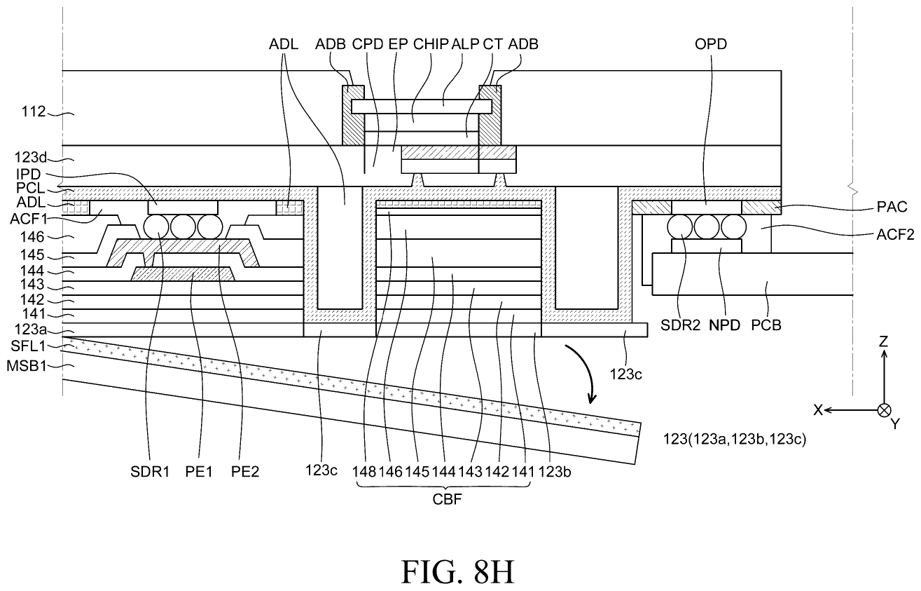

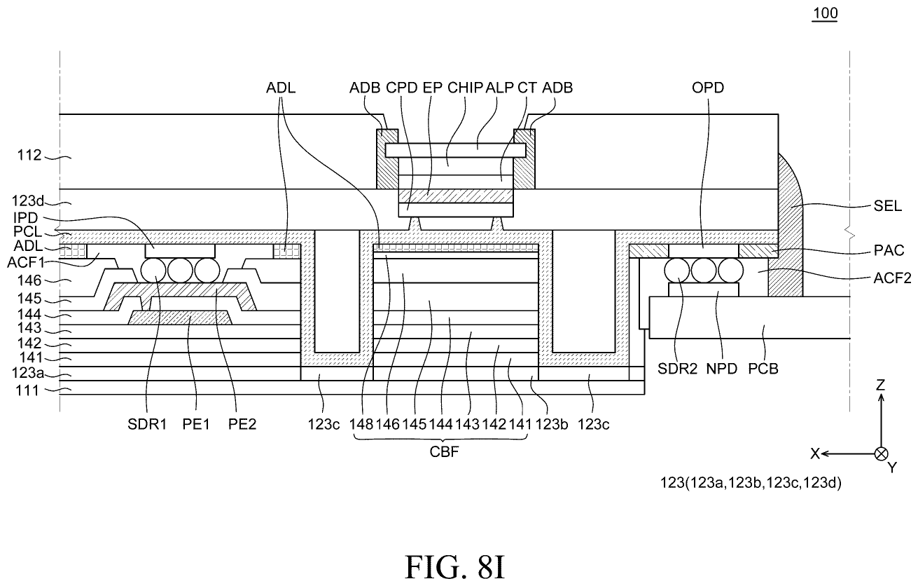

FIGS. 8A to 8I are process charts illustrating a manufacturing method of a display device according to exemplary embodiments of the present disclosure.

In the meantime, in FIGS. 8A to 8I, cross-sectional views according to the manufacturing process of the display device 100 according to the exemplary embodiment of the present disclosure which has been described with reference to FIGS. 1 to 7 are illustrated. For example, FIGS. 8A to 8I sequentially illustrate a manufacturing method of the display device 100 according to the exemplary embodiment of the present disclosure which has been described with reference to FIGS. 1 to 7.

In the meantime, in FIGS. 8A to 8I, a manufacturing method of a display device 100 is illustrated with regard to a cross-sectional structure of the display device 100 which has been described with reference to FIG. 7, among cross-sectional structures of the display device 100 according to the exemplary embodiment of the present disclosure. Accordingly, in FIGS. 8A to 8I, the manufacturing method of a display device 100 will be described with respect to the cross-sectional structure of the display device 100 which has been described with reference to FIG. 7.

In the meantime, for the convenience of description, a description which is repeated with the description which has been made with reference to FIGS. 1 to 7 will not be repeated.

In the meantime, an insulating layer, a semiconductor layer, and a metal layer which will be described with reference to FIGS. 8A to 8I may be formed by a manufacturing process of a conventional circuit element which forms the insulating layer, the semiconductor layer, and the metal layer by a coating or deposition method and selectively patterning the insulating layer, the semiconductor layer, and the metal layer by photolithography and an etching process to form various electrodes, various patterns, and signal lines. Therefore, for the convenience of description, a detailed description thereof will be omitted.

First, referring to FIG. 8A, a first sacrificial layer SFL1 may be formed on a first mother board MSB1.

The first mother board MSB1 is a substrate which supports components disposed on the lower substrate 111 during the process of manufacturing the display device 100. The first mother board MSB1 may be formed of a material having a rigidity. For example, the first mother board MSB1 may be formed of glass, but is not limited thereto.

The first mother board MSB1 may be used to simultaneously manufacture a plurality of display devices 100. For example, a plurality of cells is defined on the first mother board MSB1 and each cell may correspond to each of the plurality of manufactured display devices.

The first sacrificial layer SFL1 formed on the first mother board MSB1 is a layer used to separate a plurality of lower plate patterns 121a, a plurality of lower line patterns 122a, a plurality of lower pad plate patterns 123a and 123b, and a plurality of lower pad line patterns 123c of the display device 100 from the first mother board MSB1. The first sacrificial layer SFL1 may be formed of a material which decomposes the interfacial coupling force when laser is irradiated to weaken the adhesive strength with the plurality of lower plate patterns 121a, the plurality of lower line patterns 122a, the plurality of lower pad plate patterns 123a and 123b, and the plurality of lower pad line patterns 123c of the display device 100. For example, the first sacrificial layer SFL1 may be formed by silicon nitride (SiNx) or silicon oxide (SiOx) or a laminated structure of silicon nitride and silicon oxide. The first sacrificial layer SFL1 may be formed by depositing silicon nitride and silicon oxide on the entire surface of the first mother board MSB1, but is not limited thereto.

Next, the plurality of lower pad plate patterns 123a and 123b and the plurality of lower pad line patterns 123c may be provided on the first sacrificial layer SFL1 and a plurality of inorganic insulating layers may be provided on the plurality of lower pad plate patterns 123a and 123b. For example, the buffer layer 141, the gate insulating layer 142, the first interlayer insulating layer 143, the second interlayer insulating layer 144, the passivation layer 145, and the planarization layer 146 are provided above each of the first lower pad plate pattern 123a and the second lower pad plate pattern 123b. The first pad electrode PE1 may be provided on the first interlayer insulating layer 143 disposed on the first lower pad plate pattern 123a and the second pad electrode PE2 may be disposed on the second interlayer insulating layer 144 disposed on the first lower pad plate pattern 123a.

Next, referring to FIG. 8B, a second mother board MSB2, a second sacrificial layer SFL2 formed on the second mother board MSB2, and an upper pad plate pattern 123d formed on the second sacrificial layer SFL2 may be provided at a side opposite to the first mother board MSB1.

In the meantime, the upper pad plate pattern 123d may be provided to a side opposite to the first mother board MSB1 while providing (coupling) the pad connection line PCL onto the upper pad plate pattern 123d. Further, a chip pad CPD and an electrode pattern EP disposed on the chip pad CPD may be disposed between the upper pad plate pattern 123d and the second mother board MSB2 (or the second sacrificial layer SFL2). The chip pad CPD may be connected to the pad connection line PCL through a contact hole which passes through the upper pad plate pattern 123d. For example, the chip pad CPD and the electrode pattern EP may be provided in a part in which at least a part of the upper pad plate pattern 123d is removed.

The second mother board MSB2 is a substrate which supports components disposed on the upper substrate 112 during the process of manufacturing the display device 100. The second mother board MSB2 may be formed of a material having a rigidity. For example, the second mother board MSB2 may be formed of glass, but is not limited thereto.

The second sacrificial layer SFL2 formed on the second mother board MSB2 is a layer used to separate the upper pad plate pattern 123d of the display device 100 from the second mother board MSB2. The second sacrificial layer SFL2 may be formed of a material which decomposes the interfacial coupling force when laser is irradiated to weaken the adhesive strength with the upper pad plate pattern 123d of the display device 100. For example, the second sacrificial layer SFL2 may be formed by silicon nitride (SiNx) or silicon oxide (SiOx) or a laminated structure of silicon nitride and silicon oxide. The second sacrificial layer SFL2 may be formed by depositing silicon nitride and silicon oxide on the entire surface of the second mother board MSB2, but is not limited thereto.

Further, the upper pad plate pattern 123d may be provided at the side opposite to the first mother board MSB1 while providing (or bonding or adhering) an input pad IPD and an output pad OPD on the pad connection line PCL.

The input pad IPD may be bonded or electrically connected to the second pad electrode PE2 by the first conductive film ACF1. The pad connection line PCL may be bonded with the planarization layer 146 disposed on the first lower pad plate pattern 123a and the overcoat layer 148 disposed on the second lower pad plate pattern 123b by the adhesive layer ADL.

Next, further referring to FIG. 8C, the printed circuit board PCB and the connection pad NPD formed on the printed circuit board PCB may be provided. The connection pad NPD may be bonded and electrically connected with the output pad OPD by the second conductive film ACF2.

Next, further referring to FIG. 8D, a laser lift off (LLO) process may be performed to separate the second sacrificial layer SFL2 and the second mother board MSB2 from the upper pad plate pattern 123d of the display device 100.

Next, further referring to FIG. 8E, the driving chip CHIP may be provided on the chip pad CPD and the electrode pattern EP. For example, the chip pad CPD and the driving chip CHIP may be connected by the soldering process.

Next, the heat dissipation plate ALP may be provided on the driving chip CHIP and the driving chip CHIP may be fixed onto the upper pad plate pattern 123d by the adhesive member ADB.

Next, further referring to FIG. 8F, an insulating material 112a for forming the upper substrate 112 may be provided above the upper pad plate pattern 123d. The insulating material 112a is a material for forming the upper substrate 112 and may include an insulating material which is bendable or extendable. For example, the insulating material 112a for forming the upper substrate 112 may be a silicon rubber, such as polydimethylsiloxane (PDMS) or an elastomer such as polyurethane (PU) and polytetrafluoroethylene (PTFE).

Next, further referring to FIG. 8G, at least a part of the insulating material 112a is removed (for example, etched) using at least one mask to form the upper substrate 112. For example, the insulating material 112a which overlaps the driving chip CHIP and the heat dissipation plate ALP, among the insulating materials 112a, is removed to form the upper substrate 112. Accordingly, the heat dissipation plate ALP disposed on the driving chip CHIP may be exposed.

Next, further referring to FIG. 8H, a laser lift off (LLO) process may be performed to separate the first sacrificial layer SFL1 and the first mother board MSB1 from the plurality of lower pad plate patterns 123a and 123b and the lower pad line pattern 123c of the display device 100.

Next, further referring to FIG. 8I, the lower substrate 111 is disposed below the lowermost portion of the display device 100, and for example, a lower portion of the plurality of lower pad plate patterns 123a and 123b and the lower pad line pattern 123c and the outermost periphery of the display device 100 may be sealed by the sealant SEL.

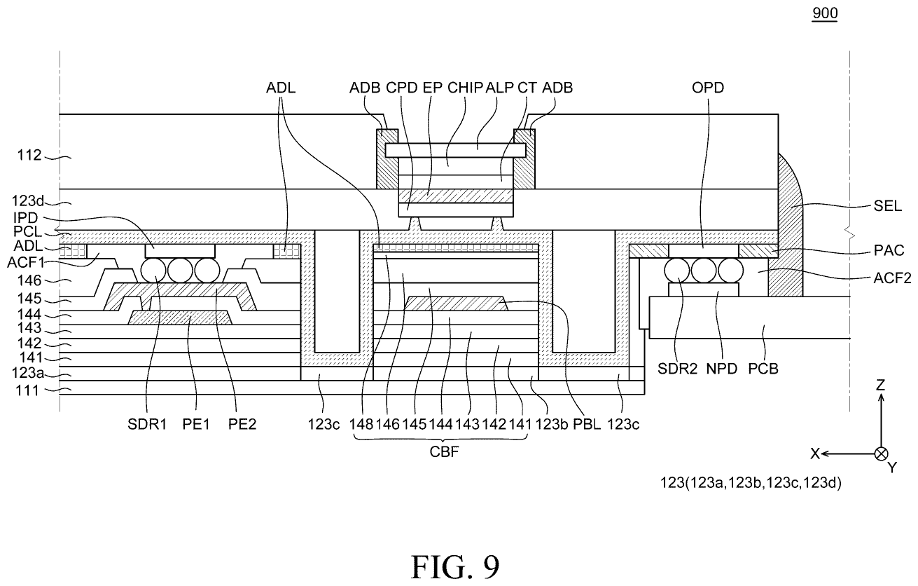

FIG. 9 is a cross-sectional view illustrating another example taken along the line V-V′ of FIGS. 5 and 6 according to exemplary embodiments of the present disclosure.

In the meantime, a display device 900 of FIG. 9 is a modified exemplary embodiment of the display device 100 which has been described with reference to FIG. 7, with regard to a pad shielding layer PBL. Accordingly, for the convenience of description, a redundant description will not be repeated.

Referring to FIG. 9, in the display device 900 according to the exemplary embodiments of the present disclosure, the pad shielding layer PBL may be disposed between the second interlayer insulating layer 144 and the passivation layer 145 disposed on the second lower pad plate pattern 123b. For example, the pad shielding layer PBL may be disposed on the second interlayer insulating layer 144 and the passivation layer 145 may be disposed on the second interlayer insulating layer 144 so as to cover at least a part of the pad shielding layer PBL.

The pad shielding layer PBL may include a metal material. For example, the pad shielding layer PBL may include any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but the material of the pad shielding layer PBL is not limited thereto.

In one exemplary embodiment, the pad shielding layer PBL disposed on the second interlayer insulating layer 144 on the second lower pad plate pattern 123b may include the same material as the source electrode 153 and the drain electrodes 154 and 164 disposed on the second interlayer insulating layer 144 on the plurality of lower plate patterns 121a disposed in the active area AA and the second pad electrode PE2 disposed on the second interlayer insulating layer 144 on the first lower pad plate pattern 123a. For example, the pad shielding layer PBL disposed on the second interlayer insulating layer 144 on the second lower pad plate pattern 123b may be simultaneously formed by the same process as the source electrode 153 and the drain electrodes 154 and 164 disposed on the second interlayer insulating layer 144 on the plurality of lower plate patterns 121a disposed in the active area AA and the second pad electrode PE2 disposed on the second interlayer insulating layer 144 on the first lower pad plate pattern 123a. However, the exemplary embodiment of the present disclosure is not limited thereto.

As described above, the display device 900 according to the exemplary embodiment of the present disclosure includes the pad shielding layer PBL formed of a metal material in the chip buffer unit CBF disposed on the second lower pad plate pattern 123b on which the driving chip CHIP is located. Therefore, static electricity, which may be applied to the driving chip CHIP may be shielded.

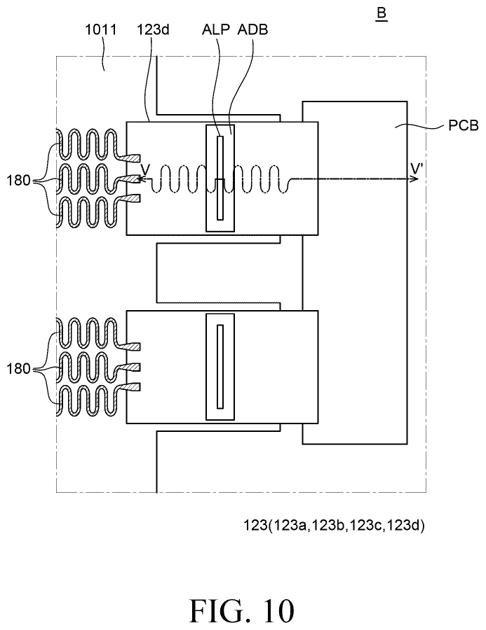

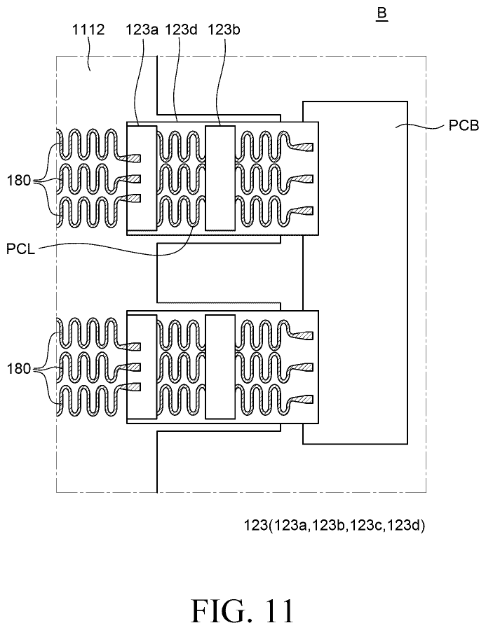

FIGS. 10 and 11 are enlarged plan views illustrating another example of a part B of FIG. 1 according to exemplary embodiments of the present disclosure.

In the meantime, FIGS. 10 and 11 illustrate a modified exemplary embodiment for FIGS. 5 and 6 with regard to a lower substrate 1011 and an upper substrate 1112. Accordingly, for the convenience of description, a redundant description will not be repeated.

Referring to FIGS. 10 and 11, each of the lower substrate 1011 and the upper substrate 1112 may include a protruding portion which protrudes along the first direction X. For example, the protruding portion included in the lower substrate 1011 and the upper substrate 1112 may overlap an area in which the plurality of pad patterns 123 is disposed.

As described above, in FIGS. 10 and 11, the lower substrate 1011 and the upper substrate 1112 include a protruding portion which is formed so as to overlap the area in which the plurality of pad patterns 123 is disposed. In an area which does not overlap the area in which the plurality of pad patterns 123 is disposed, the lower substrate 1011 and the upper substrate 1112 are not disposed so that the stretchability of the display device may be further improved.

As described above, in a display device according to the exemplary embodiments of the present disclosure, a driving chip and a plurality of pads connected thereto may be disposed in a stretchable pad area.

Accordingly, according to the exemplary embodiments of the present disclosure, the display device may be stretchable in a pad area in which a driving chip and a plurality of pads connected thereto are disposed.

The exemplary embodiments of the present disclosure can also be described as follows:

According to an embodiment of the present disclosure, there is provided a display device. The display device includes a lower substrate which is divided into an active area and a non-active area and is stretchable, a plurality of pixels which is disposed in the active area and on the lower substrate, a plurality of connection lines which is disposed on the lower substrate and is connected to each of the plurality of pixels, an upper substrate which is opposite to the lower substrate and is stretchable, and a pad pattern which is disposed in the non-active area between the lower substrate and the upper substrate. The pad pattern may include a first lower pad plate pattern on which an input pad is disposed, a second lower pad plate pattern on which a chip pad connected to the input pad through a pad connection line and a driving chip connected to the chip pad are disposed, a lower pad line pattern which connects the first lower pad plate pattern and the second lower pad plate pattern, and an upper pad plate pattern which is disposed on the first lower pad plate pattern, the second lower pad plate pattern, and the lower pad line pattern.

The pad connection line may be disposed below the upper pad plate pattern.

The chip pad and the driving chip may be disposed above the upper pad plate pattern.

The pad connection line may be connected to the chip pad through a contact hole which passes through the upper pad plate pattern.

The display device may include a heat dissipation plate disposed on the driving chip.

The upper substrate may include an opening which exposes at least a part of a top surface of the heat dissipation plate.

The display device may include a chip buffer unit which is disposed between the pad connection line and the second lower pad plate pattern and includes a plurality of insulating layers.

The display device may include a pad shielding layer which is disposed between the plurality of insulating layers included in the chip buffer unit and includes a metal material.

The input pad may be disposed below the pad connection line to be connected to the pad connection line.

The display device may include a pad electrode which is disposed between the first lower pad plate pattern and the input pad and is connected to the input pad by a first conductive film.

The pad electrode may be connected to each of the plurality of pixels through the plurality of connection lines.

The display device may include an output pad which is disposed below the pad connection line to be connected to the pad connection line.

The output pad may not overlap the first lower pad plate pattern and the second lower pad plate pattern.

The display device may include a connection pad which is disposed below the output pad and is connected to the output pad by a second conductive film.

The display device may include a printed circuit board connected to the connection pad.

The first lower pad plate pattern and the second lower pad plate pattern may be disposed to be spaced apart from each other along one direction.

On a plane, the upper pad plate pattern may overlap the first lower pad plate pattern, the second lower pad plate pattern, and the lower pad line pattern.

According to an embodiment of the present disclosure, there is provided a display device. The display device includes a lower substrate which is divided into an active area and a non-active area and is stretchable, a plurality of pixels which is disposed in the active area and on the lower substrate, a plurality of connection lines which is disposed on the lower substrate and is connected to each of the plurality of pixels, an upper substrate which is opposite to the lower substrate and is stretchable, a pad pattern which is disposed in the non-active area between the lower substrate and the upper substrate, and a driving chip disposed on the pad pattern. The pad pattern may include a plastic material.

The pad pattern may include at least one of polyimide, polyacrylate, and polyacetate.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope of the present disclosure thereof should be construed as falling within the scope of the present disclosure.

What is claimed is:

1. A display device comprising:
a lower substrate that is divided into an active area and a non-active area and is stretchable;
a plurality of pixels in the active area and on the lower substrate;
a plurality of connection lines on the lower substrate and connected to each of the plurality of pixels;
an upper substrate that is opposite to the lower substrate and is stretchable; and
a pad pattern in the non-active area between the lower substrate and the upper substrate,
wherein the pad pattern includes:
a first lower pad plate pattern on which an input pad is disposed;
a second lower pad plate pattern on which a chip pad connected to the input pad through a pad connection line and a driving chip connected to the chip pad are disposed;
a lower pad line pattern that connects the first lower pad plate pattern and the second lower pad plate pattern; and
an upper pad plate pattern on the first lower pad plate pattern, the second lower pad plate pattern, and the lower pad line pattern.

2. The display device according to claim 1, wherein the pad connection line is below the upper pad plate pattern.

3. The display device according to claim 2, wherein the chip pad and the driving chip are above the upper pad plate pattern.

4. The display device according to claim 3, wherein the pad connection line is connected to the chip pad through a contact hole that passes through the upper pad plate pattern.

5. The display device according to claim 3, further comprising:
a heat dissipation plate on the driving chip.

6. The display device according to claim 5, wherein the upper substrate includes an opening that exposes at least a part of a top surface of the heat dissipation plate.

7. The display device according to claim 2, further comprising:
a chip buffer unit between the pad connection line and the second lower pad plate pattern, the chip buffer unit including a plurality of insulating layers.

8. The display device according to claim 7, further comprising:
a pad shielding layer which is disposed between the plurality of insulating layers included in the chip buffer unit and includes a metal material.

9. The display device according to claim 2, wherein the input pad is below the pad connection line and connected to the pad connection line.

10. The display device according to claim 9, further comprising:
a pad electrode between the first lower pad plate pattern and the input pad, the pad electrode connected to the input pad by a first conductive film.

11. The display device according to claim 10, wherein the pad electrode is connected to each of the plurality of pixels through the plurality of connection lines.

12. The display device according to claim 2, further comprising:
an output pad below the pad connection line and connected to the pad connection line.

13. The display device according to claim 12, wherein the output pad is non-overlapping with the first lower pad plate pattern and the second lower pad plate pattern.

14. The display device according to claim 12, further comprising:
a connection pad below the output pad and connected to the output pad by a second conductive film.

15. The display device according to claim 14, further comprising:
a printed circuit board connected to the connection pad.

16. The display device according to claim 1, wherein the first lower pad plate pattern and the second lower pad plate pattern are spaced apart from each other along one direction.

17. The display device according to claim 1, wherein on a plane, the upper pad plate pattern overlaps the first lower pad plate pattern, the second lower pad plate pattern, and the lower pad line pattern.

18. A display device comprising:
a lower substrate that is divided into an active area and a non-active area and is stretchable;
a plurality of pixels in the active area and on the lower substrate;
a plurality of connection lines on the lower substrate and connected to each of the plurality of pixels;
an upper substrate that is opposite to the lower substrate and is stretchable;
a pad pattern in the non-active area between the lower substrate and the upper substrate; and
a driving chip on the pad pattern,
wherein the pad pattern includes a plastic material.

19. The display device according to claim 18, wherein the pad pattern includes at least one of polyimide, polyacrylate, or polyacetate.
